(19) United States
(12) Patent Application Publication
(10) Pub. No.: US 2022/0146791 A1
(43) Pub. Date: May 12, 2022

(54) OPTICAL IMAGING SYSTEM COMPRISING COMPOSITE LENS SURFACE AND IMAGING DEVICE COMPRISING THE SAME, AND METHOD OF DESIGNING COMPOSITE LENS SURFACE

(71) Applicant: CoAsia Optics Corp., Yongin-si (KR)

(72) Inventors: Junho MUN, Yongin-si (KR); Yeong Hyeon KIM, Gwangju-si (KR); Byoung Suk CHOI, Yongin-si (KR); Won Young CHOI, Seongnam-si (KR)

(73) Assignee: CoAsia Optics Corp., Yongin-si (KR)

(21) Appl. No.: 17/481,532

(22) Filed: Sep. 22, 2021

(30) Foreign Application Priority Data
Nov. 10, 2020 (KR) 10-2020-0149153

(51) Int. Cl. G02B 13/00; G02B 9/64; G02B 3/04

(52) U.S. Cl. CPC G02B 13/0045; G02B 2003/0093; G02B 3/04; G02B 9/64

(57) ABSTRACT

An optical imaging system includes one or more lens surfaces divided into a plurality of areas, wherein adjacent areas among the plurality of areas are surfaces expressed by different equations, and light passing through each of the plurality of areas may be imaged on the image surface of the same image sensor. According to the disclosure, it is possible to form a composite lens surface by composing different shapes of curved surfaces on a lens surface constituting an optical imaging system and increase a design freedom of the optical imaging system. Further, it is possible to significantly improve optical characteristics of the optical imaging system, such as increasing the definition of image or the MTF property and the like. By applying plurality of such divided surface areas, it is also possible to optimize, synthesize, or manipulate the optical characteristics of the optical imaging system relevant to each interested field area.

### CROSS-REFERENCE TO RELATED APPLICATIONS

This application claims the priority of Korean Patent Application No. 10-2020-0149153 filed on Nov. 10, 2020, in the Korean Intellectual Property Office, the disclosure of which is incorporated herein by reference.

### BACKGROUND OF THE INVENTION

### Field of the Invention

The present disclosure relates to an optical imaging system, and more particularly, to an optical imaging system and an imaging device including the same capable of obtaining a clearer image by applying one or more lens surfaces in which curved surfaces having different shapes are composed.

### Description of the Related Art

In general, an optical system comprises a plurality of lenses of dispersing or converging light, and a lens surface of each lens is formed of one of a spherical surface, an aspherical surface, and a planar surface. Further, in the past, spherical lenses were widely used, but recently, a use range of aspherical lenses with more excellent aberration correction performance than the spherical lens has been significantly increased.

Particularly, in recent years, as a high-pixel image sensor of 10 mega or more is universally used in small electronic devices such as a smartphone, a small optical system that applies aspherical surface to most of lens surfaces has also been frequently used to minimize a total length while exhibiting high-resolution performance corresponding to high pixel.

The aspherical shape of the lens is expressed as equation, and a lens designer may obtain a desired aspherical shape by appropriately adjusting coefficients of basic functions representing the aspherical surface.

Most of lens designers design an optical system using optical design software, and determine the aspherical shape by determining an aspherical coefficient set that matches a target specification while changing the aspherical coefficients.

However, various shapes of aspherical surfaces may be designed while changing the coefficient set of the basis function as such, but it is virtually impossible to represent all desired curved surfaces without errors with one finite basis function set.

Particularly, in the case of a high-pixel smartphone optical system which has been recently applied, it is required to design and manufacture a very precise lens, and there also occurs frequently that optical characteristics to be targeted are not implemented even by a small error within 1 μm occurring in the lens surface.

Accordingly, in theoretically describing and manufacturing the shapes of the lens surface, there is a need for a method of having a more freedom and expressing more various surface shapes than a conventional method of representing a lens surface with one aspherical coefficient set, thereby improving the lens performance in the same restriction conditions.

Accordingly, it is required to provide a new method capable of implementing more various shapes of curved surfaces beyond the conventional method of forming one aspherical surface or one spherical surface determined by one finite basis function set and a coefficient set, on one lens surface.

Meanwhile, in Korean patent publication No. 10-2006-0119808, there is disclosed an objective lens for an optical pickup apparatus in which one lens surface is divided into a plurality of sections with concentric shapes and each section has a different aspherical shape.

However, the objective lens of the patent publication is for optical pickup, not for imaging, and has a limitation of being not available for imaging because the aspherical surface of each section is formed to have a different focal length corresponding to a different specification of CD or DVD, and a step of a lens surface sag between adjacent sections is allowed.

Further, in a device for finally obtaining an image focusing well on various object distances, there is a disclosed a multiple curvature lens for similarly adjusting a point spread function of different object distances by forming a plurality of curved surfaces with different curvatures on one lens surface and dispersing focuses of light passing through each curved surface. However, when the multiple curvature lens is used, there is an effect of increasing depth of focus, but there is a problem that the definition of the image is entirely lowered as compared with a single curvature lens for obtaining a clear image.

The above-described technical configuration is the background art for helping in the understanding of the present invention, and does not mean a conventional technology widely known in the art to which the present invention pertains.

### SUMMARY OF THE INVENTION

The present disclosure is derived under the underground, and an object of the present disclosure is to provide a method capable of improving optical characteristics such as a MTF property of an image and the like, while increasing a design freedom of an optical imaging system so as to use optical lenses with more various shapes.

To achieve the objects, an aspect of the present disclosure provides an optical imaging system including one or more lens surfaces divided into a plurality of areas, wherein adjacent areas among the plurality of areas are surfaces expressed by different equations, and light passing through each of the plurality of areas is imaged on the image surface of the same image sensor.

In the optical imaging system according to an aspect of the present disclosure, the adjacent areas among the plurality of areas may be aspherical or spherical surfaces expressed by different equations.

In the optical imaging system according to an aspect of the present disclosure, the adjacent areas among the plurality of areas may have the same sag height of the lens surface or the same slope on the boundary.

In the optical imaging system according to an aspect of the present disclosure, the plurality of areas may be one of a rotationally symmetric surface, a non-rotationally symmetric surface, and a freeform surface, respectively.

In the optical imaging system according to an aspect of the present disclosure, the plurality of areas may be formed on the last lens surface of the optical system.

In the optical imaging system according to an aspect of the present disclosure, the adjacent areas among the plurality of areas may be expressed by the same or different basis functions selected from an xⁿ aspherical function, a Q_{con} aspherical function, a Q_{bsf} aspherical function, and a Zernike function.

Another aspect of the present disclosure provides an imaging device including an image sensor; and an optical imaging system including one or more lens surfaces divided into a plurality of areas, wherein adjacent areas among the plurality of areas are surfaces expressed by different equations, and light passing through each of the plurality of areas is imaged on the image surface of the image sensor.

In the imaging device according to the present disclosure, the adjacent areas among the plurality of areas of the optical imaging system may be aspherical or spherical surfaces expressed by different equations.

Yet another aspect of the present disclosure provides a method of designing a composite lens surface to be applied to a lens surface of an optical imaging system, the method including the steps of: calculating basic design values of a lens surface using inputted basic data; and determining a basis including a basis element of which similarity (s) satisfies a predetermined condition as compared with the basic design values for a predetermined range on the lens surface, but determining coefficients of the basis so that sag heights of a lens surface by a curved surface function of a first area and a lens surface by a curved surface function of a second area are the same or slopes are the same as each other on a boundary of the first surface area and the second surface area adjacent to each other.

According to the present disclosure, it is possible to form a composite lens surface which has not been implemented in the related art by composing different shapes of curved surfaces on a lens surface constituting an optical imaging system and increase a design freedom of the optical imaging system.

Further, it is possible to significantly improve optical characteristics of the optical imaging system, such as increasing the definition of image or the MTF property, and the like. By applying plurality of such divided surface areas, it is also possible to optimize, synthesize, or manipulate the optical characteristics of the optical imaging system relevant to each interested field area.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a configuration diagram of an optical system according to a first embodiment of the present disclosure;

FIG. 1B is an optical path diagram of the optical system according to the first embodiment of the present disclosure;

FIG. 2 is a diagram illustrating area division of a lens surface as an example;

FIG. 3 is a diagram illustrating aspherical curves corresponding to first to third areas of FIG. 2, respectively;

FIGS. 4A and 4B are a configuration diagram and an optical path diagram of an optical system according to comparative example;

FIGS. 5A and 5B are a compared graph illustrating aberration curves of the optical system according to the first embodiment of the present disclosure and the optical system according to comparative example;

FIGS. 6A, 6B, 7A, 7B, 8A and 8B are diagrams of comparing MTF curves at various spatial frequencies in the optical system according to the first embodiment of the present disclosure and the optical system according to comparative example;

FIGS. 9A and 9B are a configuration diagram and a graph illustrating aberration curves of an optical system according to a second embodiment of the present disclosure, respectively;

FIGS. 10A and 10B are a configuration diagram and a graph illustrating aberration curves of an optical system according to a third embodiment of the present disclosure, respectively;

FIG. 10C is a diagram illustrating division positions of each lens surface in the optical system according to the third embodiment of the present disclosure;

FIGS. 11A and 11B are a configuration diagram and a graph illustrating aberration curves of an optical system according to a fourth embodiment of the present disclosure, respectively;

FIGS. 12A and 12B are a configuration diagram and a graph illustrating aberration curves of an optical system according to a fifth embodiment of the present disclosure, respectively;

FIGS. 13A and 13B are a configuration diagram and a graph illustrating aberration curves of an optical system according to a sixth embodiment of the present disclosure, respectively;

FIGS. 14A and 14B are a configuration diagram and a graph illustrating aberration curves of an optical system according to a seventh embodiment of the present disclosure, respectively;

FIGS. 15A and 15B are a configuration diagram and a graph illustrating aberration curves of an optical system according to an eighth embodiment of the present disclosure, respectively;

FIG. 16 is a flowchart illustrating a method of designing an optical system according to an embodiment of the present disclosure; and

FIG. 17 is a block diagram illustrating a configuration of a computing device for implementing the method of designing the optical system according to an embodiment of the present disclosure.

### DETAILED DESCRIPTION OF THE PREFERRED EMBODIMENT

First, in the accompanying drawings of this specification, there are parts indicated with actually different dimensions or ratios, but this is for convenience of description and understanding, and thus, it should be noted in advance that the scope of the present disclosure should not be limitedly interpreted. Further, in this specification, when an element is connected, coupled, or electrically connected to the other element, the element is not only directly connected, coupled, or electrically connected to the other element, but also indirectly connected, coupled, or electrically connected to the other element with other elements interposed therebetween. Also, when an element is directly connected or coupled to the other element, it is meant that the element is connected or coupled to the other element without other elements therebetween. In addition, when a certain part includes a certain element, unless otherwise indicated, it means that other elements may be further included rather than excluding other elements. In addition, in this specification, since expressions such as front, rear, left, right, upper, and lower are relative concepts that may vary depending on viewing positions, the scope of the present disclosure is not necessarily limited to the corresponding expressions.

Hereinafter, preferred embodiments of the present disclosure will be described with reference to the drawings. Further, for convenience of description, a configuration, a design method, a design device, and the like of an optical system according to an embodiment of the present disclosure will be described in sequence.

1. Optical Imaging System Including Composite Lens Surface

### First Embodiment

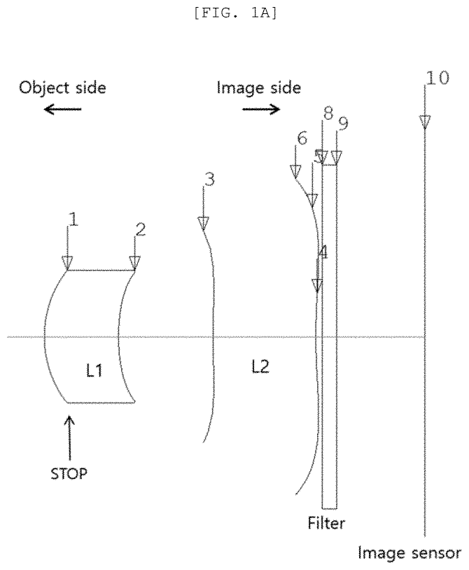

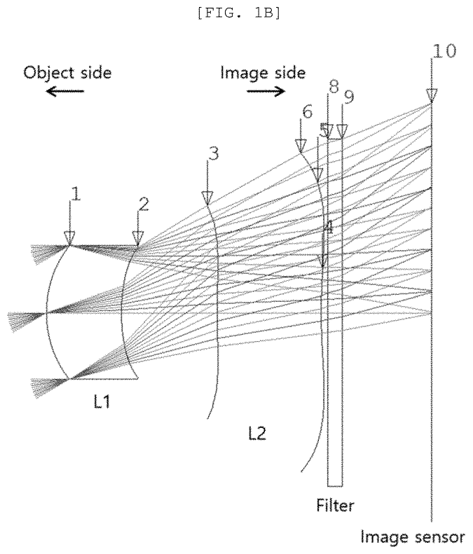

FIGS. 1A and 1B are a configuration diagram and an optical path diagram of the optical imaging system according to a first embodiment of the present disclosure.

As illustrated in FIG. 1, the optical imaging system according to the first embodiment of the present disclosure includes a first lens L1 and a second lens L2 which are disposed sequentially from an object side to an image side.

The first lens L1 has refractive power and may have both aspherical surfaces of which an object side surface is convex and an image side surface is concave.

The second lens L2 has refractive power and may have both aspherical surfaces of which an object side surface is convex in a paraxial region and an image side surface is concave in a paraxial region.

Particularly, in the first embodiment of the present disclosure, it is characterized that both surfaces of the first lens L1 and the object side surface of the second lens L2 are formed in single aspherical surfaces, respectively, but the image side surface of the second lens L2 is formed by composing a plurality of different curved surfaces (aspherical surfaces or spherical surfaces).

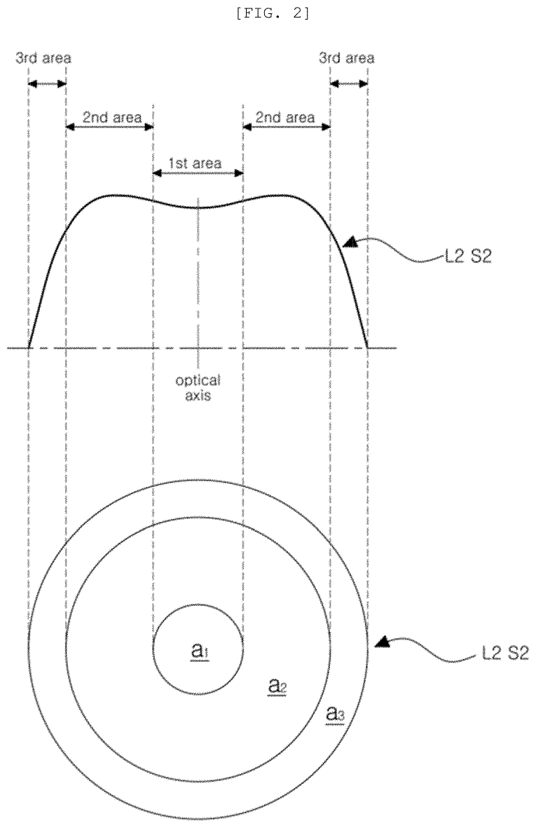

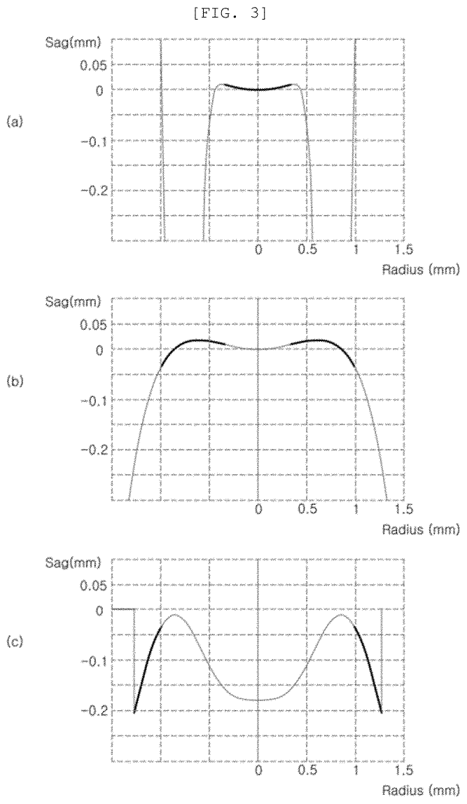

Referring to FIGS. 2 and 3, in the first embodiment of the present disclosure, an image side surface L2S2 of the second lens L2 is divided into a first area a₁ with a predetermined radius based on an optical axis, a second annular area a₂ surrounding the first area a₁, and a third annular area a₃ surrounding the second area a₂, and different aspherical surfaces are formed in the respective areas a₁, a₂, and a₃.

That is, the lens surface L2S2 illustrated in FIG. 2 is not a curved surface represented by a single aspherical function, and the curved surface of the first area a₁ is formed by taking only a portion corresponding to the area a₁ in the aspherical surface of graph (a) illustrated in FIG. 3, the curved surface of the second area a₂ is formed by taking only a portion corresponding to the area a₂ in the aspherical surface of graph (b) illustrated in FIG. 3, and the curved surface of the third area a₃ is formed by taking only a portion corresponding to the area a₃ in the aspherical surface of graph (c) illustrated in FIG. 3.

Meanwhile, as illustrated in the optical path diagram of FIG. 1B, light passing through the composite lens surface L2S2 of the second lens L2 is imaged on an image sensor surface even if the light passes through the curved surface of any area a₁, a₂, and a₃. Accordingly, according to the embodiment of the present disclosure, it is possible to acquire a clear image unlike a conventional multifocal lens or multiple curvature lens.

Further, in FIGS. 1A and 1B, only an effective radius portion at which the second lens L2 contributes to optical characteristics has been expressed, and the specific shape of an edge needs to be determined later in consideration of assembling and the like.

In the first embodiment of the present disclosure, the aspherical surface of each lens surface may be implemented by using a xⁿ aspherical (powered series) basis such as the following Equation 1.

$$Z ( r ) = \frac{\frac{{r}^{2}}{R}}{1 + \sqrt{1 - ( 1 + k ) \frac{{r}^{2}}{{R}^{2}}}} + {Ar}^{4} + {Br}^{6} + {Cr}^{8} + {Dr}^{10} \qquad < Equation 1 >$$

Wherein, Z(r) represents a lens surface sag in a z-axial direction, r represents a radial distance in a direction vertical to a z axis, R represents a radius of curvature, k represents a conic constant, and A, B, C, D, . . . represent aspherical coefficients.

Through the Equation 1 above (hereinafter, referred to as an ‘xⁿ aspherical function’ for convenience in this specification), it can be seen that the aspherical shape varies when the aspherical coefficients A, B, C, D, vary.

According to the first embodiment of the present disclosure, the both surfaces of the first lens L1 and the object side surface of the second lens L2 are single aspherical surfaces expressed by one aspherical equation, respectively.

Therefore, the entire shape of each lens surface may be implemented by substituting a suitable aspherical coefficient, a radius of curvature, and a conic constant for the xⁿ aspherical function, respectively.

On the other hand, the image side surface L2S2 of the second lens L2 is divided into the first to third areas a₁, a₂, and a₃, and since a composite lens surface needs to be formed by implementing a curved surface having a different shape for each area, a different aspherical equation for each of the areas a₁, a₂, and a₃ needs to be applied.

If the xⁿ function is used as the aspherical basis, as shown in the following Equation 2, a plurality of aspherical surfaces calculated by applying a separate coefficient set for each of the areas a₁, a₂, and a₃ are composed to implement a composite lens surface.

$$Z ( r ) = \frac{\frac{{r}^{2}}{{R}_{1}}}{1 + \sqrt{1 - ( 1 + k ) \frac{{r}^{2}}{{R}_{1}^{2}}}} + {A}_{1} {r}^{4} + {B}_{1} {r}^{6} + {C}_{1} {r}^{8} + {D}_{1} {r}^{10} . . . ( \vert r \vert \leq {r}_{1} ) \\ Z ( r ) = \frac{\frac{{r}^{2}}{{R}_{2}}}{1 + \sqrt{1 - ( 1 + {k}_{2} ) \frac{{r}^{2}}{{R}_{2}^{2}}}} + {A}_{2} {r}^{4} + {B}_{2} {r}^{6} + {C}_{2} {r}^{8} + {D}_{2} {r}^{10} . . . ( {r}_{1} \leq \vert r \vert \leq {r}_{2} ) \\ . . . \\ Z ( r ) = \frac{\frac{{r}^{2}}{{R}_{i}}}{1 + \sqrt{1 - ( 1 + {k}_{i} ) \frac{{r}^{2}}{{R}_{i}^{2}}}} + {A}_{i} {r}^{4} + {B}_{i} {r}^{6} + {C}_{i} {r}^{8} + {D}_{i} {r}^{10} . . . ( {r}_{i - 1} \leq \vert r \vert \leq {r}_{i} ) \\ . . . \\ Z ( r ) = \frac{\frac{{r}^{2}}{{R}_{n}}}{1 + \sqrt{1 - ( 1 + {k}_{n} ) \frac{{r}^{2}}{{R}_{n}^{2}}}} + {A}_{n} {r}^{4} + {B}_{n} {r}^{6} + {C}_{n} {r}^{8} + {D}_{n} {r}^{10} . . . ( {r}_{n - 1} \leq \vert r \vert \leq {r}_{e} ) \qquad < Equation 2 >$$

Wherein, r represents a radial distance, rₑ represents an effective radius of the lens, |r|≤r₁ refers to a first area, r₁≤|r|≤r₂ refers to a second area, rᵢ₋₁≤|r|≤rᵢ refers to an i-th area, and rₙ₋₁≤|r|≤rₑ refers to an n-th area.

Through the Equation 2 above, it can be seen that the aspherical shape of the first area a₁ is determined by a first coefficient set (R₁, k₁, A₁, B₁, C₁, D₁, . . . ), the aspherical shape of the second area a₂ is determined by a second coefficient set (R₂, k₂, A₂, B₂, C₂, D₂, . . . ), and the aspherical shape of the i-th area aᵢ is determined by an i-th coefficient set (Rᵢ, kᵢ, Aᵢ, Bᵢ, Cᵢ, Dᵢ, . . . ).

As such, when a different aspherical surface corresponding to each area aᵢ, a₂, aᵢ, . . . , aₙ is calculated by applying a different coefficient set to each area aᵢ, a₂, aᵢ, . . . , aₙ, it is preferred to prevent a sag height difference in a boundary of each area in consideration of the optical characteristics and a mass-production property.

To this end, it is required to select an equation and/or coefficient set in which Z(r) values of adjacent areas are matched or differential values (slopes) thereof are matched on the boundary.

Meanwhile, Equation 2 above is applied when a reference position of the radial distance r is an optical axis, that is, the first to n-th areas aᵢ, a₂, . . . , aₙ are rotationally symmetric based on the optical axis.

However, when the lens surface is divided into a plurality of areas, each area needs not to be centered on the optical axis. Accordingly, a sag Z(r) of the lens surface of each area a₁, a₂, . . . , aₙ may be defined as the following Equation 3 by setting reference positions of the radial distance r expressing the divided first to n-th areas a₁, a₂, . . . , aₙ to d₁, d₂, . . . , dₙ, respectively.

$$Z ( r ) = \frac{\frac{{( r - {d}_{1} )}^{2}}{{R}_{1}}}{1 + \sqrt{1 - ( 1 + {k}_{1} ) \frac{{( r - {d}_{1} )}^{2}}{{R}_{1}^{2}}}} + {{A}_{1} ( r - {d}_{1} )}^{4} + {{B}_{1} ( r - {d}_{1} )}^{6} + {{C}_{1} ( r - {d}_{1} )}^{8} . . . ( \vert r \vert \leq {r}_{1} ) \\ Z ( r ) = \frac{\frac{{( r - {d}_{2} )}^{2}}{{R}_{2}}}{1 + \sqrt{1 - ( 1 + {k}_{2} ) \frac{{( r - {d}_{2} )}^{2}}{{R}_{2}^{2}}}} + {{A}_{2} ( r - {d}_{2} )}^{4} + {{B}_{2} ( r - {d}_{2} )}^{6} + {{C}_{2} ( r - {d}_{2} )}^{8} . . . ( {r}_{1} \leq \vert r \vert \leq {r}_{2} ) \\ . . . \\ Z ( r ) = \frac{\frac{{( r - {d}_{i} )}^{2}}{{R}_{i}}}{1 + \sqrt{1 - ( 1 + {k}_{i} ) \frac{{( r - {d}_{i} )}^{2}}{{R}_{i}^{2}}}} + {{A}_{i} ( r - {d}_{i} )}^{4} + {{B}_{i} ( r - {d}_{i} )}^{6} + {{C}_{i} ( r - {d}_{i} )}^{8} . . . ( {r}_{i - 1} \leq \vert r \vert \leq {r}_{i} ) \\ . . . \\ Z ( r ) = \frac{\frac{{( r - {d}_{n} )}^{2}}{{R}_{n}}}{1 + \sqrt{1 - ( 1 + {k}_{n} ) \frac{{( r - {d}_{n} )}^{2}}{{R}_{n}^{2}}}} + {{A}_{n} ( r - {d}_{n} )}^{4} + {{B}_{n} ( r - {d}_{n} )}^{6} + {{C}_{n} ( r - {d}_{n} )}^{8} . . . ( {r}_{n - 1} \leq \vert r \vert \leq {r}_{c} ) \qquad < Equation 3 >$$

Meanwhile, recently, since cases of using different types of aspherical basis functions instead of the xⁿ aspherical function tend to be increased, various types of aspherical basis functions may be used to express a complicated aspherical shape and improve the efficiency of the design.

For example, a single aspherical surface or a composite lens surface may also be implemented by using aspherical basis functions such as a Q_{con} aspherical function, a Q_{bsf} aspherical function, a Zernike function, and the like.

The Q_{con} aspherical function is a function defined so that an aspherical rms sag error is minimized based on a conic term, and is expressed by the following Equation 4.

$${Z}_{con} ( r ) = \frac{{cr}^{2}}{1 + \sqrt{1 - ( 1 + k ) {c}^{2} {r}^{2}}} + {D}_{con} ( u ) \\ {D}_{con} ( u ) = {u}^{4} {\sum }_{m = 0}^{M} {a}_{m} {Q}_{m}^{con} ( {u}^{2} ) \qquad < Equation 4 >$$

Wherein, u=r/rₘₐₓ, rₘₐₓ represents a maximum radius, aₘ represents a Q_{con} aspherical coefficient, and Qₘ^{con}(u²) s represent independent terms corresponding to m.

Further, the Q_{bsf} aspherical function is expressed by the following Equation 5.

$${Z}_{bfs} ( r ) = \frac{{c}_{bfs} {r}^{2}}{1 + \sqrt{1 - {c}_{bfs}^{2} {r}^{2}}} + {D}_{bfs} ( u ) \\ {D}_{bfs} ( u ) = \frac{{u}^{2} ( 1 - {u}^{2} )}{\sqrt{1 - {c}_{bfs}^{2} {r}_{max}^{2} {u}^{2}}} {\sum }_{m = 0}^{M} {a}_{m} {Q}_{m}^{bfs} ( {u}^{2} ) \qquad < Equation 5 >$$

Wherein, u=r/rₘₐₓ, rₘₐₓ represents a maximum radius, c_{bfs} represents a curvature corresponding to a best fitting sphere, aₘ represents a aspherical coefficient, and Qₘ^{bfs} (u²)s represent independent terms corresponding to m.

The detailed design specification of the optical imaging system according to the first embodiment of the present disclosure is shown in the Table 1 below, and the aspherical coefficients applied to each lens surface are shown in the Table 2.

TABLE 1
Design specification according to first embodiment
of the present disclosure

| Surface | | Surface | Sphere/ | Radius of | Thickness/ | Refractive | Abbe |
|---|---|---|---|---|---|---|---|
| No. | Component | Name | Asphere | curvature (mm) | distance (mm) | Index (Nd) | Number (Vd) |
| 1 (Stop) | 1st lens | L1 S1 | Asphere | 0.8429 | 0.5775 | 1.535 | 55.71 |
| 2 | | L1 S2 | Asphere | 1.429 | 0.7368 | | |
| 3 | 2nd lens | L2 S1 | Asphere | 6.348 | 0.7999 | 1.64 | 23.52 |
| 4 | | L2 S2-1 | Asphere | 4.194 | — | | |
| 5 | | L2 S2-2 | Asphere | 4.2 | — | | |
| 6 | | L2 S2-3 | Asphere | 4.009E−08 | 0.05046 | | |
| 8 | Filter | | Sphere | Infinity | 0.11 | 1.517 | 64.17 |
| 9 | | | Sphere | Infinity | 0.69 | | |
| 10 | Image sensor | | Sphere | Infinity | | | |

TABLE 2
Aspherical coefficients of first embodiment of the
present disclosure

| Surface name | L1 S1 | L1 S2 | L2 S1 | L2 S2-1 | L2 S2-2 | L2 S2-3 |
|---|---|---|---|---|---|---|
| Surface No. | 1 | 2 | 3 | 4 | 5 | 6 |
| R | 8.429E−01 | 1.429E+00 | 6.348E+00 | 4.194E+00 | 4.200E+00 | 4.009E−08 |
| K | −5.899E−01 | 5.346E+00 | −4.895E−03 | −1.002E+00 | −2.677E+01 | −8.091E+01 |
| A | 1.164E−01 | −1.560E−01 | −1.995E−01 | −1.550E−01 | −1.381E−01 | 2.282E+00 |
| B | 8.035E−01 | 4.808E+00 | −7.131E−01 | 1.415E−02 | 3.695E−02 | −5.084E+00 |
| C | −3.270E+00 | −3.652E+01 | 2.766E+00 | −1.307E+00 | −2.112E−02 | 4.580E+00 |
| D | 9.908E+00 | 1.372E+02 | −4.694E+00 | 4.891E+00 | 8.507E−04 | −1.967E+00 |
| E | −9.627E+00 | −1.873E+02 | 2.786E+00 | −9.805E+00 | −1.154E−05 | 3.298E−01 |

In the optical imaging system according to the first embodiment of the present disclosure, a total length (TTL) is 2.96 mm, an effective focal length (EFL) is 2.82 mm, F-No is 2.7, and a diagonal length of an image sensor is 3.2 mm.

Further, an effective radius (rₑ) of the image side surface L2S2 of the second lens L2 divided into the three areas is 1.262 mm and area divided positions are r₁=0.339 mm and r₂=1.000 mm.

Through the Tables 1 and 2 above, it can be confirmed that all coefficient sets (R, k, A, B, C, D, E) applied to three areas L2S2-1, L2S2-2, and L2S2-3 divided on the image side surface L2S2 of the second lens L2 are different from each other, and as a result, it can be seen that each area is formed of each different aspherical surface.

Hereinafter, the characteristics of the optical system according to the first embodiment of the present disclosure will be described as compared with those of comparative example.

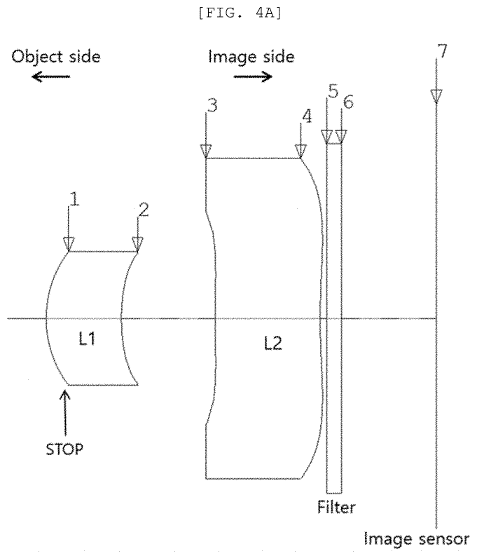

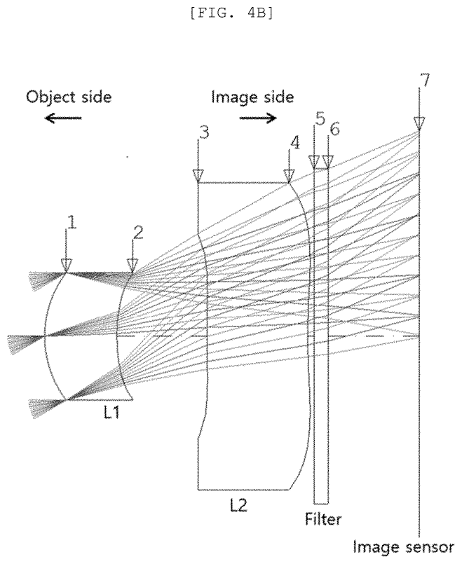

First, a configuration diagram and an optical path diagram of the optical system according to comparative example are as illustrated in FIGS. 4A and 4B.

Further, the following Table 3 illustrates a design specification of comparative example and the Table 4 illustrates aspherical coefficients applied to each lens surface of the first and second lenses L1 and L2 used in comparative example.

TABLE 3
Design specification of optical system according to comparative example

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 (Stop) | 1st lens | L1 S1 | Asphere | 0.8431 | 0.5729 | 1.535 | 55.71 |
| 2 | | L1 S2 | Asphere | 1.435 | 0.7141 | | |
| 3 | 2nd lens | L2 S1 | Asphere | 7.126 | 0.8 | 1.64 | 23.52 |
| 4 | | L2 S2 | Asphere | 4.695 | 0.05 | | |
| 5 | Filter | | Sphere | Infinity | 0.11 | 1.517 | 64.17 |
| 6 | | | Sphere | Infinity | 0.7253 | | |
| 7 | Image | | Sphere | Infinity | | | |
| | sensor | | | | | | |

TABLE 4
Aspherical coefficients of optical system
according to comparative example

| Surface name | L1 S1 | L1 S2 | L2 S1 | L2 S2 |
|---|---|---|---|---|
| Surface No. | 1 | 2 | 3 | 4 |
| R | 8.431E−01 | 1.435E+00 | 7.126E+00 | 4.695E+00 |
| K | −5.981E−01 | 5.496E+00 | 1.856E−01 | −1.001E+00 |
| A | 1.170E−01 | −1.679E−01 | −1.823E−01 | −1.532E−01 |
| B | 8.084E−01 | 4.959E+00 | −7.607E−01 | −2.385E−02 |
| C | −3.246E+00 | −3.797E+01 | 2.967E+00 | 1.054E−01 |
| D | 9.783E+00 | 1.431E+02 | −5.111E+00 | −9.279E−02 |
| E | −9.618E+00 | −1.975E+02 | 3.096E+00 | 2.421E−02 |

In the optical system according to comparative example, a total length (TTL) is 2.97 mm, an effective focal length (EFL) is 2.82 mm, F-No is 2.7, and a diagonal length of an image sensor is 3.2 mm.

The TTL of the optical system according to the first embodiment of the present disclosure is 2.96 mm, the TTL of comparative example is 2.97 mm, and the diagonal lengths of the image sensor are the same as each other as 3.2 mm. Further, in the first embodiment and comparative example, the thicknesses and the distance of the first lens L1 and the second lens L2 are extremely similar to each other.

However, there is a difference in the image side surface L2S2 of the second lens L2. That is, the image side surface L2S2 is a composite surface composed of the three aspherical surfaces in the first embodiment of the present disclosure and a single aspherical surface in the comparative example.

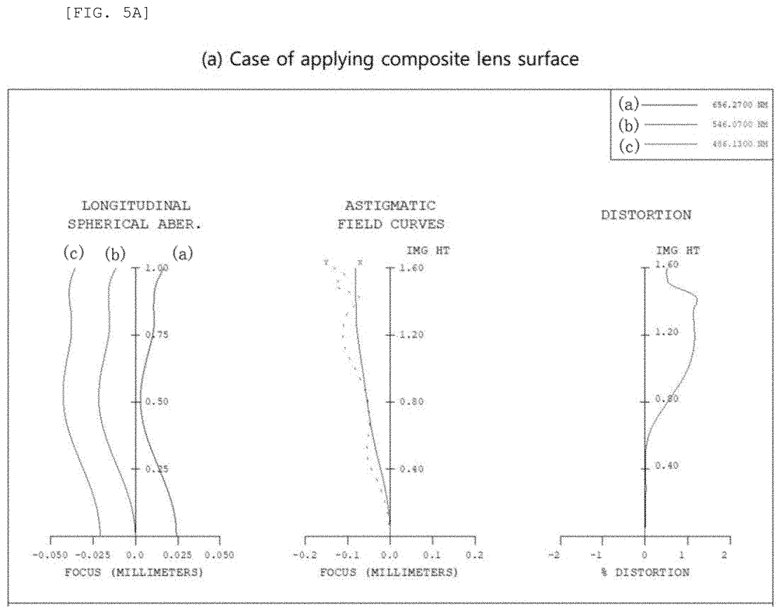

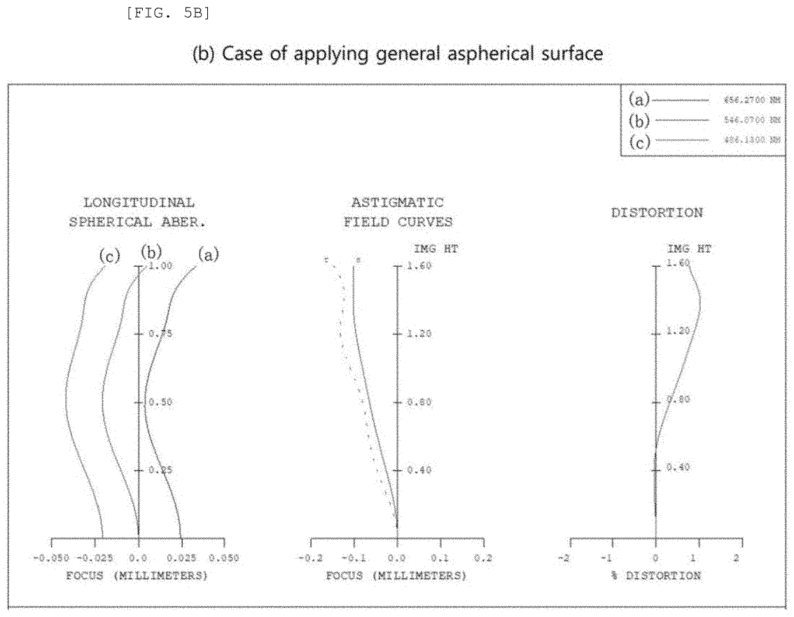

First, referring to the graph illustrating aberration curves of FIGS. 5A and 5B, it can be seen that a spherical aberration, an astigmatic aberration, and a distortion aberration all are within a conventional allowable range.

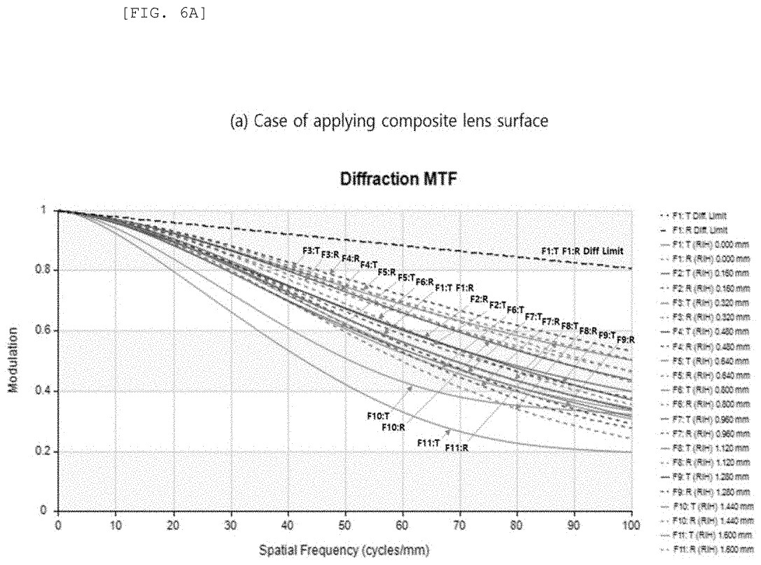

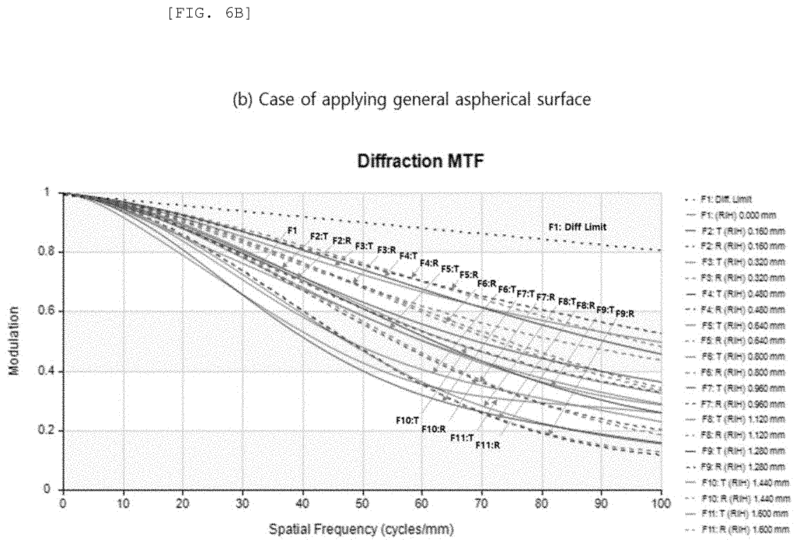

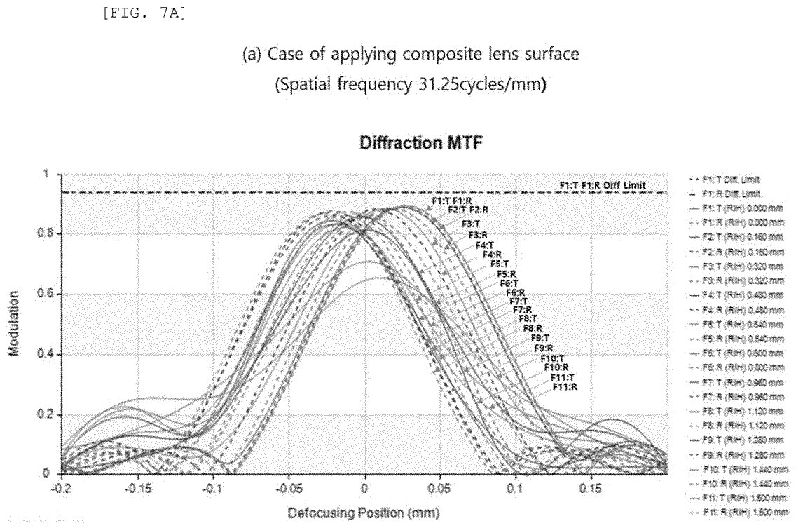

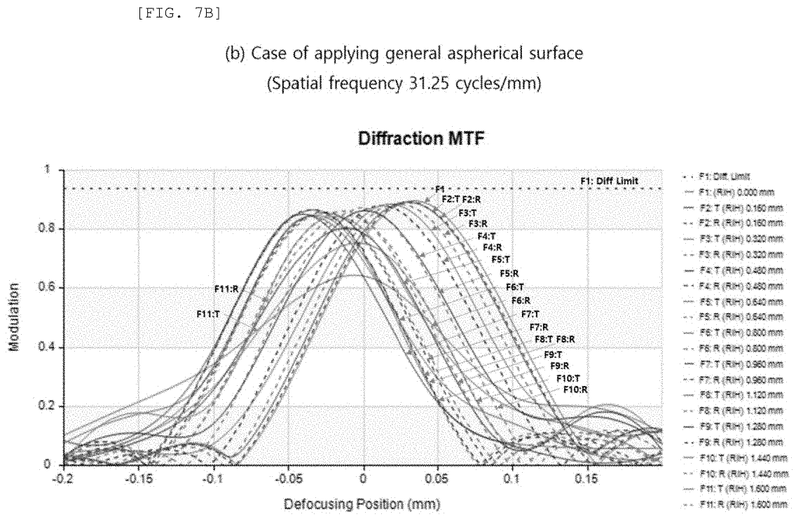

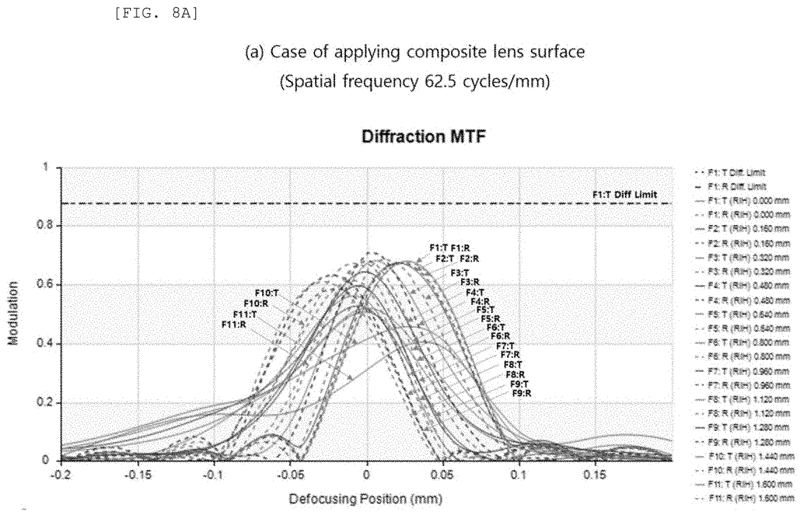

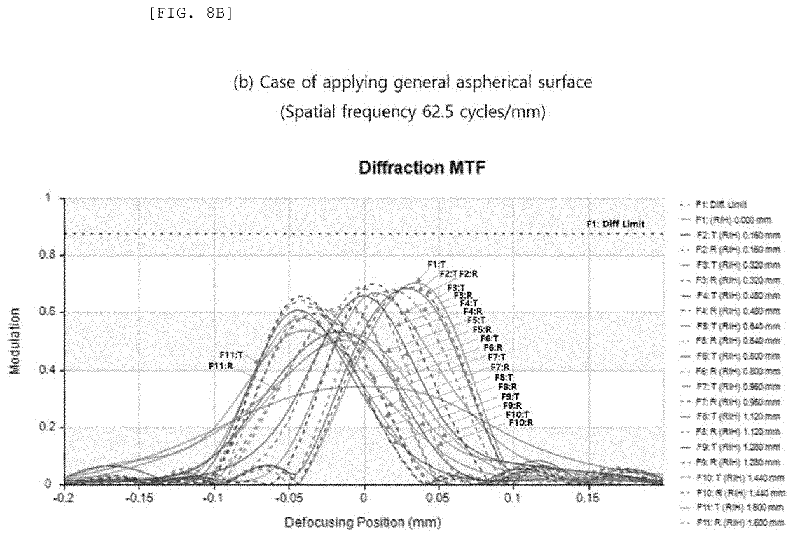

Next, when describing a through focus modulation transfer function (MTF) property for each field, as can be seen through FIGS. 6A to 8B, it can be confirmed that the optical system according to the first embodiment of the present disclosure shows a much more uniform characteristic than the comparative example applied with the single aspherical surface.

Through such a characteristic, it can be seen that the optical system according to the first embodiment of the present disclosure may acquire a more uniform and clearer image from the center to the peripheral area of the image sensor.

Further, referring to FIGS. 6A to 8B, the optical system according to the first embodiment of the present disclosure exhibits a more uniform characteristic even when a spatial frequency is increased. Through this, it can be seen that the optical system according to the present disclosure is more suitable to exhibit the high-resolution performance for a high-pixel image sensor.

Meanwhile, it is impossible to exactly express the whole composite lens surface applied to the first embodiment of the present disclosure with one aspherical basis function set, but it is possible to mathematically fit the composite curved surface. However, according to a simulation result, it was confirmed that the aspherical surface fitted by the mathematical method as such is difficult to be applied to actual products because the optical performance such as MTF and the like is deteriorated, and in some cases, the optical performance is significantly lowered.

Hereinabove, the case of applying the composite lens surface to the optical system consisting of two pieces of lenses has been described. However, since the embodiment of the present disclosure is not limited thereto, as shown in the following various embodiments, the aforementioned composite lens surface may be applied even to an optical system including more pieces of lenses.

### Second Embodiment

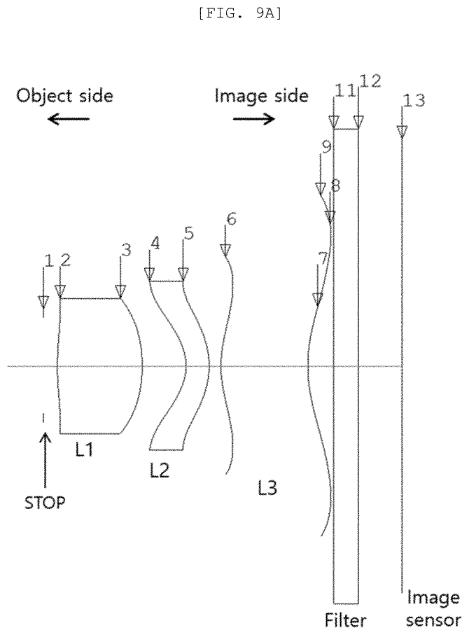

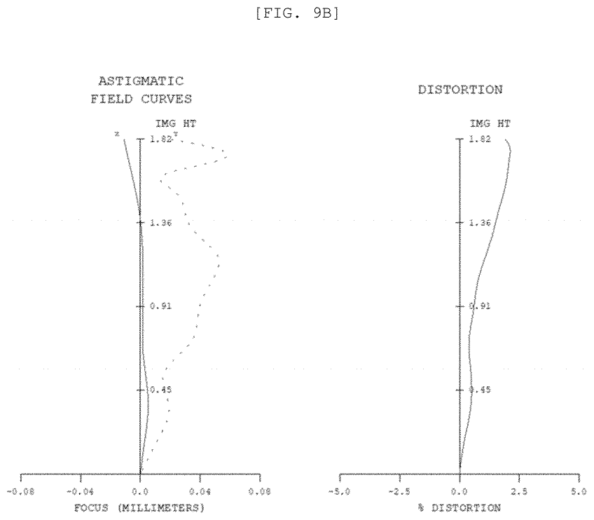

FIGS. 9A and 9B are a configuration diagram and a graph illustrating aberration curves of the optical imaging system according to a second embodiment of the present disclosure.

As illustrated in FIG. 2, the optical imaging system according to the second embodiment of the present disclosure includes a first lens L1, a second lens L2, and a third lens L3 which are disposed sequentially from an object side to an image side.

The first lens L1 has refractive power and may be a lens of which both surfaces are convex.

The second lens L2 has refractive power and may be a lens of which an object side surface is concave and an image side surface is convex.

The third lens L3 has refractive power and may be a lens of which an object side surface is convex in a paraxial region and an image side surface is concave in a paraxial region.

All lens surfaces of the first to third lenses L1, L2, and L3 may also be aspherical surfaces, and at least one lens surface may also be a spherical surface.

However, in the optical imaging system according to the second embodiment of the present disclosure, an image side surface L3S2 of the third lens L3 is formed of a composite lens surface divided into three areas L3S2-1, L3S2-2, and L3S2-3.

A detailed design specification of the optical imaging system according to the second embodiment of the present disclosure is shown in the Table 5 below, and the aspherical coefficients applied to each lens surface are shown in the Table 6.

TABLE 5
Design specification according to second embodiment of the present disclosure

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 | Stop | | Sphere | Infinity | 0.1184 | | |
| 2 | 1st lens | L1 S1 | Asphere | 2.557 | 0.7178 | 1.547 | 60.33 |
| 3 | | L1 S2 | Asphere | −1.131 | 0.3718 | | |
| 4 | 2nd lens | L2 S1 | Asphere | −0.3923 | 0.1953 | 1.68 | 19.24 |
| 5 | | L2 S2 | Asphere | −0.6444 | 0.1 | | |
| 6 | 3rd lens | L3 S1 | Asphere | 0.9072 | 0.7358 | 1.547 | 60.33 |
| 7 | | L3 S2-1 | Asphere | 1.212 | — | | |
| 8 | | L3 S2-2 | Asphere | 1.052 | — | | |
| 9 | | L3 S2-3 | Asphere | 1.371 | 0.22 | | |
| 11 | Filter | | Sphere | Infinity | 0.21 | 1.517 | 64.17 |
| 12 | | | Sphere | Infinity | 0.3700 | | |
| 13 | Image | | Sphere | Infinity | | | |
| | sensor | | | | | | |

TABLE 6
Aspherical coefficients of second embodiment of the present disclosure

| | Surface name | | | | | | | |
|---|---|---|---|---|---|---|---|---|
| Surface | L1 S1 | S2 | L2 S1 | S2 | L3 S1 | L3 S2-1 | L3 S2-2 | L3 S2-3 |
| No. | 2 | 3 | 4 | 5 | 6 | 7 | 8 | 9 |
| R | 2.557E+00 | −1.131E+00 | −3.923E−01 | −6.444E−01 | 9.072E−01 | 2.121E+00 | 1.052E+00 | 1.371E+00 |
| k | 1.043E+01 | 1.059E+00 | −8.040E−01 | −4.915E−01 | −3.396E+00 | −9.225E+00 | −1.130E+01 | −1.164E+01 |
| A | −6.235E−01 | −7.583E−02 | 3.254E+00 | 1.135E+00 | −8.168E−01 | 3.157E−01 | 9.531E−02 | −2.598E−01 |
| B | 1.339E+02 | −1.975E+00 | −1.847E+01 | −5.405E+00 | 1.476E+00 | −1.821E+00 | −1.702E−01 | 2.946E+00 |
| C | −3.235E+03 | 2.266E+01 | 9.769E+01 | 2.502E+01 | −2.802E+00 | 4.447E+00 | −4.939E−01 | −9.664E+00 |
| D | 4.051E+03 | 1.906E+03 | −2.560E+02 | −4.504E+01 | 4.614E+00 | −5.742E+00 | 1.718E+00 | 1.511E+01 |
| E | −2.916E+04 | 1.056E+03 | 3.373E+02 | 3.674E+01 | −6.124E+00 | 4.288E+00 | −2.342E+00 | −1.346E+01 |
| F | 1.195E+05 | −3.410E+03 | −1.787E+02 | −1.028E+01 | 5.435E+00 | −1.921E+00 | 1.761E+00 | 7.235E+00 |
| G | −2.590E+05 | 5.835E+03 | 0.000E+00 | 0.000E+00 | −3.176E+00 | 5.096E−01 | −7.629E−01 | −2.330E+00 |
| H | 2.312E+05 | −4.111E+03 | 0.000E+00 | 0.000E+00 | 1.606E+00 | −7.390E−02 | 1.782E−01 | 4.149E−01 |
| J | 0.000E+00 | 0.000E+00 | 0.000E+00 | 0.000E+00 | −6.736E−01 | 4.516E−03 | −1.738E−02 | −3.148E−02 |

In the optical imaging system of the second embodiment of the present disclosure, a total length (TTL) is 2.92 mm, an effective focal length (EFL) is 1.95 mm, F-No is 2.5, and a diagonal length of an image sensor is 3.63 mm.

Further, an effective radius (rₑ) of the image side surface L3S2 of the third lens L3 is 1.52 mm and positions divided into three areas are r₁=0.5 mm, and r₂=1.2 mm.

Through the Tables 5 and 6 above, it can be confirmed that all coefficient sets (R, k, A, B, C, D, E, F, G, H, J) applied to the three areas L3S2-1, L3S2-2, and L3S2-3 divided on the image side surface L3S2 of the third lens L3 are different from each other, and as a result, it can be seen that each area is formed of each different aspherical surface.

### Third Embodiment

In the first and second embodiments of the present disclosure, the composite lens surfaces were formed on the last lens surfaces, respectively, but the formation positions of the composite lens surfaces are not limited thereto, but the composite lens surfaces may be formed at various positions.

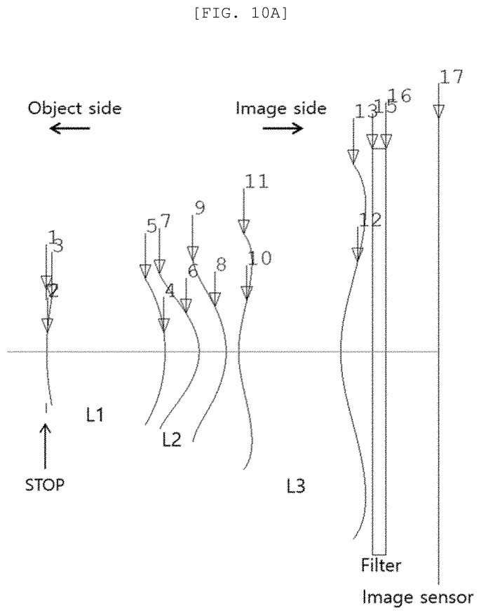

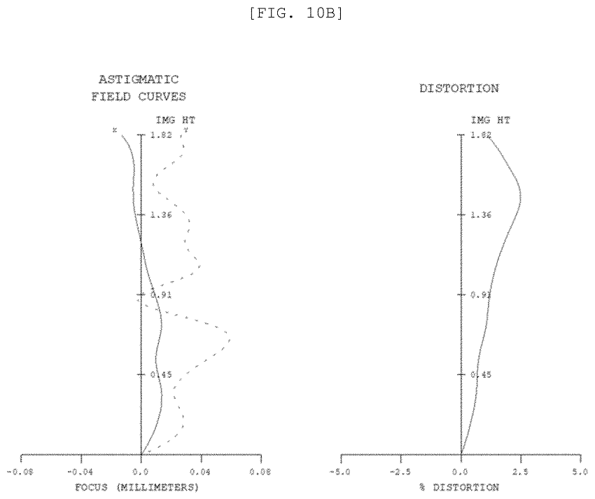

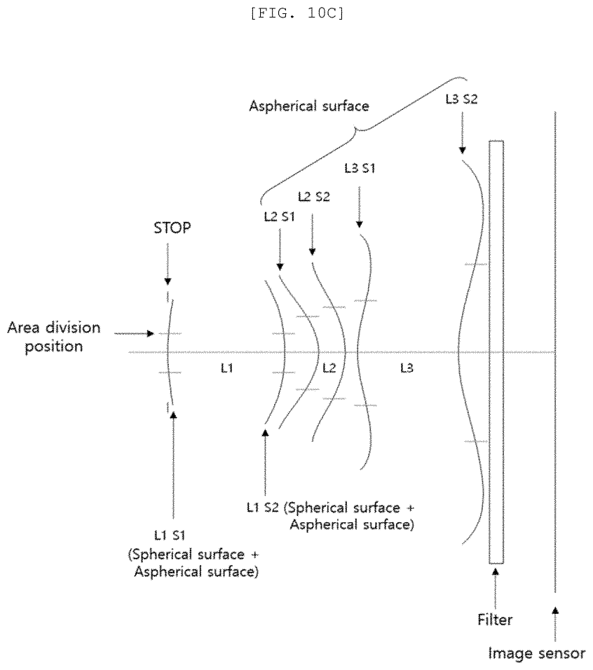

A third embodiment of the present disclosure relates to an optical system having composite lens surfaces formed on all lens surfaces, and FIGS. 10A and 10B illustrate a configuration diagram and a graph illustrating aberration curves of the optical imaging system according to the third embodiment of the present disclosure.

Further, FIG. 10C illustrates area division positions of each lens surface in the optical imaging system according to the third embodiment of the present disclosure.

As illustrated in FIG. 10A, the optical imaging system according to the third embodiment of the present disclosure includes a first lens L1, a second lens L2, and a third lens L3 which are disposed sequentially from an object side to an image side.

The first lens L1 has refractive power and may be a lens of which both surfaces are convex.

The second lens L2 has refractive power and may be a lens of which an object side surface is concave and an image side surface is convex.

The third lens L3 has refractive power and may be a lens of which an object side surface is convex in a paraxial region and an image side surface is concave in a paraxial region.

In the third embodiment of the present disclosure, all lens surfaces of the first to third lenses L1, L2, and L3 consist of composite lens surfaces including spherical or aspherical surfaces.

The detailed design specification of the optical imaging system according to the third embodiment of the present disclosure is shown in the Table 7 below, and the aspherical coefficients applied to each lens surface are shown in the Table 8.

TABLE 7
Design specification according to third embodiment of the present disclosure

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 | Stop | | Sphere | Infinity | 0 | | |
| 2 | 1st lens | L1 S1-1 | Sphere | 1.995 | — | 1.547 | 60.33 |
| 3 | | L1 S1-2 | Asphere | 2.036 | 0.9264 | | |
| 4 | | L1 S2-1 | Sphere | −1.243 | — | | |
| 5 | | L1 S2-2 | Asphere | −1.243 | 0.2673 | | |
| 6 | 2nd lens | L2 S1-1 | Asphere | −0.389 | — | 1.68 | 19.24 |
| 7 | | L2 S1-2 | Asphere | −0.3874 | 0.21.07 | | |
| 8 | | L2 S2-1 | Asphere | −0.654 | — | | |
| 9 | | L2 S2-2 | Asphere | −0.6559 | 0.0980 | | |
| 10 | 3rd lens | L3 S1-1 | Asphere | 0.9231 | — | 1.547 | 60.33 |
| 11 | | L3 S1-2 | Asphere | 1.024 | 0.7982 | | |
| 12 | | L3 S2-1 | Asphere | 1.317 | 0.21 | | |
| 13 | | L3 S2-2 | Asphere | 2.715 | 0.2459 | | |
| 15 | Filter | | Sphere | Infinity | 0.11 | 1.517 | 64.17 |
| 16 | | | Sphere | Infinity | 0.4111 | | |
| 17 | Image | | Sphere | Infinity | | | |
| | sensor | | | | | | |

TABLE 8
Aspherical coefficients of third embodiment of the present disclosure

| | Surface name | | | | | |
|---|---|---|---|---|---|---|
| Surface | L1 S1-1 | L1 S1-2 | L1 S2-1 | L1 S2-2 | L2 S1-1 | L2 S1-2 |
| No. | 2 | 3 | 4 | 5 | 6 | 7 |
| R | 1.995E+00 | 2.036E+00 | −1.243E+00 | −1.243E+00 | −3.890E−01 | −3.874E−01 |
| k | 0.000E+00 | 7.884E+00 | 0.000E+00 | 8.194E−01 | −7.931E−01 | −8.045E−01 |
| A | 0.000E+00 | −7.430E−01 | 0.000E+00 | 1.462E−01 | 2.784E+00 | 2.069E+00 |
| B | 0.000E+00 | 5.681E+01 | 0.000E+00 | −5.554E+00 | 1.378E+01 | 1.097E+01 |
| C | 0.000E+00 | −2.179E+03 | 0.000E+00 | 5.628E+01 | −8.255E+02 | −2.997E+02 |
| D | 0.000E+00 | 4.546E+04 | 0.000E+00 | −3.906E+02 | 1.250E+04 | 2.836E+03 |
| E | 0.000E+00 | −5.764E+05 | 0.000E+00 | 1.936E+03 | −9.826E+04 | −1.451E+04 |
| F | 0.000E+00 | 4.554E+06 | 0.000E+00 | −6.430E+03 | 4.465E+05 | 4.456E+04 |
| G | 0.000E+00 | −2.188E+07 | 0.000E+00 | 1.348E+04 | −1.174E+06 | −8.241E+04 |
| H | 0.000E+00 | 5.848E+07 | 0.000E+00 | −1.603E+04 | 1.658E+06 | 8.480E+04 |
| J | 0.000E+00 | −6.664E+07 | 0.000E+00 | 8.182E+03 | −9.719E+05 | −3.736E+04 |
| | Surface name | | | | | |
| Surface | L2 S2-1 | L2 S2-2 | L3 S1-1 | L3 S1-2 | L3 S2-1 | L3 S2-2 |
| No. | 8 | 9 | 10 | 11 | 12 | 13 |
| R | −6.540E−01 | −6.559E−01 | 9.231E−01 | 1.024E+00 | 1.317E+00 | 2.715E+00 |
| k | −4.417E−01 | −4.147E−01 | −1.954E+00 | −1.781E+00 | −8.812E+00 | 8.997E+00 |
| A | 1.257E+00 | 7.292E−01 | −7.673E−01 | −1.030E−01 | 2.415E−01 | 2.665E−01 |
| B | −6.861E+00 | −5.419E−01 | −1.571E+00 | −6.610E+00 | −1.318E+00 | −4.176E−01 |
| C | −4.039E+00 | −1.689E+01 | 2.053E+01 | 3.916E+01 | 3.037E+00 | −1.593E−01 |
| D | 3.943E+02 | 1.586E+02 | −9.985E+01 | −1.269E+02 | −4.132E+00 | 9.243E−01 |
| E | −2.616E+03 | −5.401E+02 | 2.858E+02 | 2.568E+02 | 3.368E+00 | −1.048E+00 |
| F | 8.620E+03 | 9.034E+02 | −4.941E+02 | −3.310E+02 | −1.652E+00 | 6.068E−01 |
| G | −1.579E+04 | −6.751E+02 | 5.025E+02 | 2.621E+02 | 4.771E−01 | −1.981E−01 |
| H | 1.530E+04 | 3.834E+01 | −2.761E+02 | 1.153E+02 | −7.482E−02 | 3.405E−02 |
| J | −6.112E+03 | 1.558E+02 | 6.319E+01 | 2.125E+01 | 4.915E−03 | −2.436E−03 |

In the optical imaging system according to the third embodiment of the present disclosure, a total length (TTL) is 3.07 mm, an effective focal length (EFL) is 1.98 mm, F-No is 2.5, and a diagonal length of an image sensor is 3.63 mm.

An effective radius (rₑ) of an object side surface L1S1 of the first lens L1 is 0.418 mm and the object side surface L1S1 is divided into a first area L1S1-1 and a second area L1S1-2 based on r₁=0.15 mm. Further, the first area L1S1-1 is a spherical surface and the second area L1S1-2 is an aspherical surface, and accordingly, the object side surface L1S1 of the first lens L1 is formed of a composite lens surface including spherical and aspherical surfaces.

An effective radius (rₑ) of an image side surface L1S2 of the first lens L1 is 0.570 mm and the image side surface L1S2 is divided into a first area L1S2-1 and a second area L1S2-2 based on r₁=0.15 mm. Further, the first area L1S2-1 is a spherical surface and the second area L1S2-2 is an aspherical surface, and accordingly, the image side surface L1S2 of the first lens L1 is formed of a composite lens surface including spherical and aspherical surfaces.

An effective radius (rₑ) of an object side surface L2S1 of the second lens L2 is 0.609 mm and the object side surface L2S1 is divided into a first area L2S1-1 and a second area L2S1-2 based on r₁=0.3 mm. Further, the first area L2S1-1 and the second area L2S1-2 are aspherical surfaces having different shapes from each other, and accordingly, the object side surface L2S1 of the second lens L2 is formed of a composite lens surface including different aspherical surfaces.

An effective radius (rₑ) of an image side surface L2S2 of the second lens L2 is 0.715 mm and the image side surface L2S2 is divided into a first area L2S2-1 and a second area L2S2-2 based on r₁=0.35 mm. Further, the first area L2S2-1 and the second area L2S2-2 are aspherical surfaces having different shapes from each other, and accordingly, the image side surface L2S2 of the second lens L2 is formed of a composite lens surface including different aspherical surfaces.

An effective radius (rₑ) of an object side surface L3S1 of the third lens L3 is 0.936 mm and the object side surface L3S1 is divided into a first area L3S1-1 and a second area L3S1-2 based on r₁=0.4 mm. Further, the first area L3S1-1 and the second area L3S1-2 are aspherical surfaces having different shapes from each other, and accordingly, the object side surface L3S1 of the third lens L3 is formed of a composite lens surface including different aspherical surfaces.

An effective radius (rₑ) of an image side surface L3S2 of the third lens L3 is 1.571 mm and the image side surface L3S2 is divided into a first area L3S2-1 and a second area L3S2-2 based on r₁=0.7 mm. Further, the first area L3S2-1 and the second area L3S2-2 are aspherical surfaces having different shapes from each other, and accordingly, the image side surface L3S2 of the third lens L3 is formed of a composite lens surface including different aspherical surfaces.

Through the Tables 7 and 8 above, it can be confirmed that all coefficients sets (R, k, A, B, C, D, E, F, G, H, J) applied to the divided areas L1S1-1, L1S1-2, L1S2-1, L1S2-2, L2S1-1, L2S1-2, L2S2-1, L2S2-2, L3S1-1, L3S1-2, L3S2-1, and L3S2-2 of all the lens surfaces of the first to third lenses L1, L2, and L3 are different from each other, and as a result, it can be seen that each area is formed of each different spherical or aspherical surface.

### Fourth Embodiment

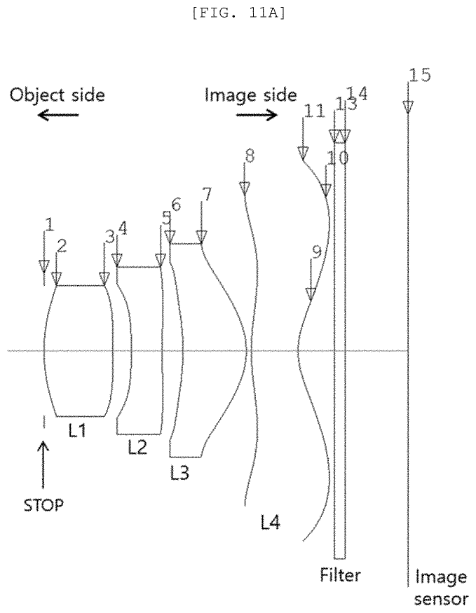

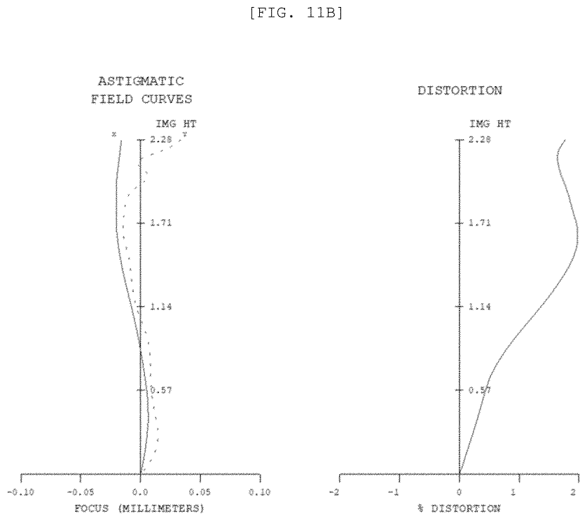

FIGS. 11A and 11B are a configuration diagram and a graph illustrating aberration curves of the optical imaging system according to a fourth embodiment of the present disclosure.

As illustrated in FIG. 11A, the optical imaging system according to the fourth embodiment of the present disclosure includes a first lens L1, a second lens L2, a third lens L3, and a fourth lens L4 which are disposed sequentially from an object side to an image side.

The first lens L1 has refractive power and may be a lens of which both surfaces are convex.

The second lens L2 has refractive power and may be a lens of which both surfaces are concave in a paraxial region.

The third lens L3 has refractive power and may be a lens of which an object side surface is concave and an image side surface is convex.

The fourth lens L4 has refractive power and may be a lens of which an object side surface is convex in a paraxial region and an image side surface is concave in a paraxial region.

All lens surfaces of the first to fourth lenses L1, L2, L3, and L4 may also be aspherical surfaces, and at least one lens surface may also be a spherical surface.

However, in the optical imaging system according to the fourth embodiment of the present disclosure, an image side surface L4S2 of the fourth lens L4 is formed of a composite lens surface divided into three areas L4S2-1, L4S2-2, and L4S2-3.

The detailed design specification of the optical imaging system according to the fourth embodiment of the present disclosure is shown in the Table 9 below, and the aspherical coefficients applied to each lens surface are shown in the Table 10.

TABLE 9
Design specification according to fourth embodiment of the present disclosure

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 | Stop | | Sphere | Infinity | 0 | | |
| 2 | 1st lens | L1 S1 | Asphere | 1.612 | 0.7014 | 1.537 | 55.71 |
| 3 | | L1 S2 | Asphere | −14.44 | 0.1866 | | |
| 4 | 2nd lens | L2 S1 | Asphere | −5.745 | 0.3137 | 1.641 | 23.85 |
| 5 | | L2 S2 | Asphere | 8.985 | 0.2115 | | |
| 6 | 3rd lens | L3 S1 | Asphere | −2.036 | 0.6431 | 1.537 | 55.71 |
| 7 | | L3 S2 | Asphere | −0.7192 | 0.0501 | | |
| 8 | 4th lens | L4 S1 | Asphere | 1.853 | 0.4752 | 1.537 | 55.71 |
| 9 | | L4 S2-1 | Asphere | 0.6441 | — | | |
| 10 | | L4 S2-2 | Asphere | 0.6011 | — | | |
| 11 | | L4 S2-3 | Asphere | −17.21 | 0.3685 | | |
| 13 | Filter | | Sphere | Infinity | 0.11 | 1.517 | 64.17 |
| 14 | | | Sphere | Infinity | 0.64 | | |
| 15 | Image | | Sphere | Infinity | | | |
| | sensor | | | | | | |

TABLE 10
Aspherical coefficients of fourth embodiment of the present disclosure

| | Surface name | | | | |
|---|---|---|---|---|---|
| Surface | L1 S1 | L1 S2 | L2 S1 | L2 S2 | L3 S1 |
| No. | 2 | 3 | 4 | 5 | 6 |
| R | 1.612E+00 | −1.444E+01 | −5.745E+00 | 8.985E+00 | −2.063E+00 |
| k | 2.883E+00 | 7.991E+01 | 2.571E+01 | −4.383E+01 | 3.506E+00 |
| A | −9.473E−02 | −3.171E−01 | −4.932E−01 | −1.111E−01 | 3.309E−01 |
| B | −1.056E+00 | 1.647E−01 | −4.024E−01 | −1.912E−02 | −1.763E−02 |
| C | 1.661E+01 | −5.645E+00 | 1.877E+00 | −4.712E−01 | −5.009E−01 |
| D | −1.697E+02 | 5.188E+01 | −1.070E+01 | 2.774E+00 | 8.714E−01 |
| E | 1.019E+03 | −2.731E+02 | 4.261E+01 | −7.439E+00 | 6.448E−01 |
| F | −3.714E+03 | 8.483E+02 | −7.472E+01 | 1.271E+01 | 2.420E−01 |
| G | 8.026E+03 | −1.531E+03 | 4.238E+01 | −1.344E+01 | −4.869E−02 |
| H | −9.456E+03 | 1.484E+03 | 2.935E+01 | 7.608E+00 | 5.031E−03 |
| J | 4.670E+03 | −5.954E+02 | −3.337E+01 | −1.711E+00 | −2.102E−04 |
| | Surface name | | | | |
| Surface | L3 S2 | L4 S1 | L4 S2-1 | L4 S2-2 | L4 S2-3 |
| No. | 7 | 8 | 9 | 10 | 11 |
| R | −7.192E−01 | 1.853E+00 | 6.441E−01 | 6.011E−01 | −1.721E+01 |
| k | −1.711E+00 | −2.851E+01 | −4.683E+00 | −5.383E+00 | 5.784E+01 |
| A | 1.682E−01 | −7.801E−02 | −1.084E−01 | −9.437E−02 | −6.667E−02 |
| B | −2.598E−01 | −3.978E−02 | −7.909E−01 | 2.866E−02 | −1.525E−03 |
| C | 2.718E−01 | 4.211E−02 | 9.875E+00 | −5.386E−03 | 2.907E−02 |
| D | −8.645E−02 | −1.260E−02 | −8.251E+01 | −7.473E−04 | 7.645E−05 |
| E | 1.396E−03 | 1.984E−03 | 5.119E+02 | 2.499E−04 | −7.907E−03 |
| F | −1.307E−03 | 1.837E−04 | −2.202E+03 | 2.832E−05 | 1.308E−03 |
| G | 7.209E−05 | 1.003E−05 | 6.088E+03 | 2.351E−06 | 7.002E−04 |
| H | −2.178E−06 | −2.987E−07 | −9.671E+03 | −1.848E−06 | −2.490E−04 |
| J | 2.774E−08 | 3.741E−09 | 6.685E+03 | −5.494E−07 | 2.259E−05 |

In the optical imaging system according to the fourth embodiment of the present disclosure, a total length (TTL) is 3.70 mm, an effective focal length (EFL) is 2.62 mm, F-No is 2.0, and a diagonal length of an image sensor is 4.57 mm.

Further, an effective radius (rₑ) of an image side surface L4S2 of the fourth lens L4 is 1.925 mm and positions divided into three areas are r₁=0.501 mm and r₂=1.550 mm.

Through the Tables 9 and 10 above, it can be confirmed that all coefficient sets (R, k, A, B, C, D, E, F, G, H, J) applied to the three areas L4S2-1, L4S2-2, and L4S2-3 divided on the image side surface L4S2 of the fourth lens L4 are different from each other, and as a result, it can be seen that each area is formed of each different aspherical surface.

### Fifth Embodiment

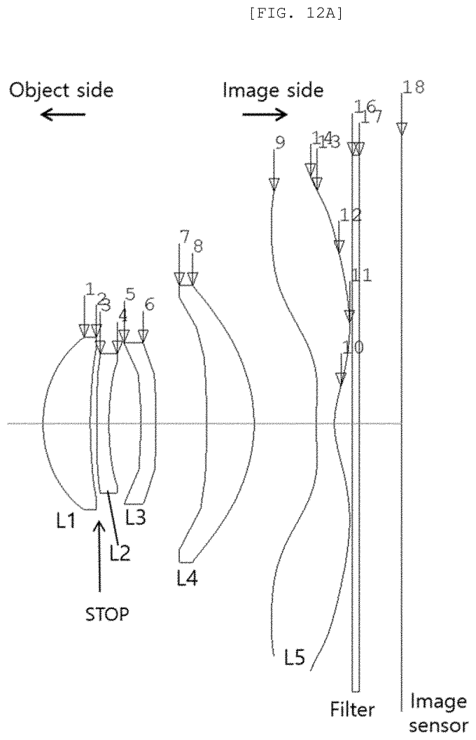

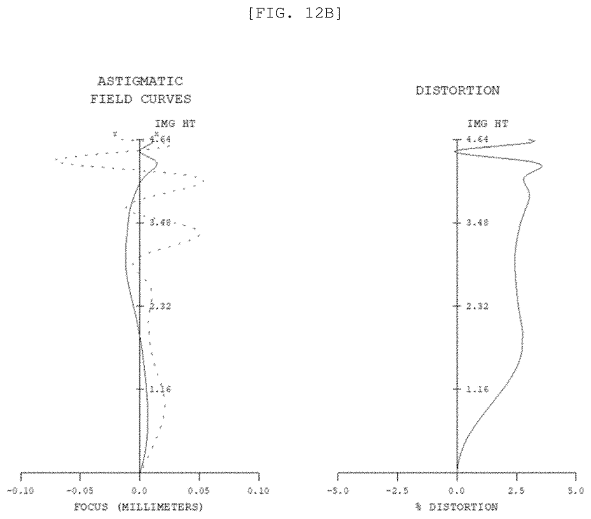

FIGS. 12A and 12B are a configuration diagram and a graph illustrating aberration curves of the optical imaging system according to a fifth embodiment of the present disclosure.

As illustrated in FIG. 12A, the optical imaging system according to the fifth embodiment of the present disclosure includes a first lens L1, a second lens L2, a third lens L3, a fourth lens L4, and a fifth lens L5 which are disposed sequentially from an object side to an image side.

The first lens L1 has refractive power and may be a lens of which an object side surface is convex and an image side surface is concave.

The second lens L2 has refractive power and may be a lens of which an object side surface is convex and an image side surface is concave.

The third lens L3 has refractive power and may be a lens of which an object side surface is convex in a paraxial region and an image side surface is concave in a paraxial region. In addition, the object side surface or the image side surface of the third lens L3 may be a plane or have large curvature close to a plane.

The fourth lens L4 has refractive power and may be a lens of which an object side surface is concave and an image side surface is convex.

The fifth lens L5 has refractive power and may be a lens of which an object side surface is convex in a paraxial region and an image side surface is concave in a paraxial region. In addition, the object side surface or the image side surface of the fifth lens L5 may include at least one inflection point.

All lens surfaces of the first to fifth lenses L1, L2, L3, L4, and L5 may also be aspherical surfaces, and at least one lens surface may also be a spherical surface.

However, in the optical imaging system according to the fifth embodiment of the present disclosure, an image side surface L5S2 of the fifth lens L5 is formed of a composite lens surface divided into five areas L5S2-1, L5S2-2, L5S2-3, L5S2-4, and L5S2-5.

The detailed design specification of the optical imaging system according to the fifth embodiment of the present disclosure is shown in the Table 11 below, and the aspherical coefficients applied to each lens surface are shown in the Table 12.

TABLE 11
Design specification according to fifth embodiment of the present disclosure

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 | 1st lens | L1 S1 | Asphere | 1.885 | 0.7673 | 1.535 | 55.71 |
| 2 | | L1 S2 | Asphere | 7.134 | 0.1038 | | |
| 3 (Stop) | 2nd lens | L2 S1 | Asphere | 13.3 | 0.2001 | 1.671 | 19.23 |
| 4 | | L2 S2 | Asphere | 4.726 | 0.5126 | | |
| 5 | 3rd lens | L3 S1 | Asphere | 64.28 | 0.2512 | 1.614 | 25.92 |
| 6 | | L3 S2 | Asphere | 56.16 | 0.8226 | | |
| 7 | 4th lens | L4 S1 | Asphere | −21.83 | 0.7719 | 1.535 | 55.71 |
| 8 | | L4 S2 | Asphere | −2.4 | 1.005 | | |
| 9 | 5th lens | L5 S1 | Asphere | 3.484 | 0.3 | 1.535 | 55.71 |
| 10 | | L5 S2-1 | Asphere | 1.273 | — | | |
| 11 | | L5 S2-2 | Asphere | 1.294 | — | | |
| 12 | | L5 S2-3 | Asphere | −9.028 | — | | |
| 13 | | L5 S2-4 | Asphere | −7.899 | — | | |
| 14 | | L5 S2-5 | Asphere | −6.754 | 0.2951 | | |
| 16 | Filter | | Sphere | Infinity | 0.11 | 1.517 | 64.17 |
| 17 | | | Sphere | Infinity | 0.6900 | | |
| 18 | Image | | Sphere | Infinity | | | |
| | sensor | | | | | | |

TABLE 12
Aspherical coefficients of fifth embodiment of the present disclosure

| | Surface name | | | | | | |
|---|---|---|---|---|---|---|---|
| Surface | L1 S1 | L1 S2 | L2 S1 | L2 S2 | L3 S1 | L3 S2 | L4 S1 |
| No. | 1 | 2 | 3 | 4 | 5 | 6 | 7 |
| R | 1.885E+00 | 7.134E+00 | 1.330E+01 | 4.726E+00 | 6.428E+01 | 5.616E+01 | −2.183E+01 |
| k | 5.812E−01 | 1.984E+01 | 9.795E+01 | 1.449E+01 | −5.249E+01 | 9.900E+01 | 2.794E+01 |
| A | −8.027E−03 | 3.975E−02 | −5.845E−02 | −3.685E−02 | −9.819E−02 | −7.278E−02 | 1.564E−03 |
| B | −9.114E−04 | 3.173E−02 | 9.254E−02 | 7.245E−02 | −3.094E−02 | −6.947E−02 | −1.393E−02 |
| C | 7.115E−03 | −1.723E−02 | −6.299E−02 | −5.192E−02 | 1.501E−01 | 2.408E−01 | 5.160E−04 |
| D | −2.644E−02 | 9.611E−03 | 2.915E−02 | 1.948E−02 | −4.918E−01 | −5.136E−01 | 5.079E−03 |
| E | 3.589E−02 | −3.689E−03 | −8.314E−03 | −4.281E−03 | 8.704E−01 | 6.481E−01 | −4.111E−03 |
| F | −2.525E−02 | 8.114E−04 | 1.418E−03 | 5.712E−04 | −9.040E−01 | −4.927E−01 | 1.438E−03 |
| G | 8.406E−03 | −9.929E−05 | −1.502E−04 | −4.556E−05 | 5.366E−01 | 2.193E−01 | −2.484E−04 |
| H | −7.198E−04 | 6.333E−06 | 9.512E−06 | 1.998E−06 | −1.644E−01 | −5.135E−02 | 2.079E−05 |
| J | −1.615E−04 | −1.647E−07 | −2.760E−07 | −3.705E−08 | 1.999E−02 | 4.829E−03 | −6.746E−07 |
| | Surface name | | | | | | |
| Surface | L4 S2 | L5 S1 | L5 S2-1 | L5 S2-2 | L5 S2-3 | L5 S2-4 | L5 S2-5 |
| No. | 8 | 9 | 10 | 11 | 12 | 13 | 14 |
| R | −2.400E+00 | 3.484E+00 | 1.273E+00 | 1.294E+00 | −9.028E+00 | −7.899E+00 | −6.754E+00 |
| k | −2.612E+00 | −9.893E+01 | −1.695E+00 | −7.482E+00 | 6.003E+00 | −2.402E−01 | 1.155E+00 |
| A | −2.264E−03 | −1.537E−01 | −4.412E−01 | −6.331E−02 | 1.877E−01 | 2.969E−02 | −1.059E−03 |
| B | −5.965E−03 | 4.961E−02 | 7.195E−01 | 1.858E−02 | −1.452E−01 | −9.403E−03 | −3.195E−05 |
| C | −7.264E−04 | −7.895E−03 | −2.179E−01 | −3.404E−03 | 6.027E−02 | 1.442E−03 | 3.312E−06 |
| D | 3.202E−03 | 7.427E−04 | −3.629E+00 | 3.453E−04 | −1.594E−02 | −1.209E−04 | 1.218E−05 |
| E | −2.017E−03 | −4.386E−05 | 1.425E+01 | 6.274E−05 | 2.819E−03 | 5.633E−06 | −2.376E−06 |
| F | 6.980E−04 | 1.639E−06 | −3.497E+01 | 2.336E−07 | −3.926E−04 | −1.358E−07 | 1.836E−07 |
| G | −1.203E−04 | −3.758E−06 | 5.882E+01 | −2.027E−05 | 2.526E−05 | 1.119E−09 | −6.389E−09 |
| H | 1.148E−05 | 4.816E−10 | −5.923E+01 | 4.535E−06 | −1.117E−06 | −1.762E−12 | 8.328E−11 |
| J | −4.347E−07 | −2.639E−12 | 2.666E+01 | −6.819E−08 | 2.194E−08 | 6.928E−13 | −8.350E−15 |

In the optical imaging system according to the fifth embodiment of the present disclosure, a total length (TTL) is 5.83 mm, an effective focal length (EFL) is 4.99 mm, F-No is 2.0, and a diagonal length of an image sensor is 9.27 mm.

Further, an effective radius (rₑ) of the image side surface L5S2 of the fifth lens L5 is 4.029 mm and positions divided into five areas are r₂=0.603 mm, r₂=1.619 mm, r₃=2.749 mm, and r₄=3.760 mm.

Through the Tables 11 and 12 above, it can be confirmed that all coefficient sets (R, k, A, B, C, D, E, F, G, H, J) applied to the five areas L5S2-1, L5S2-2, L5S2-3, L5S2-4, and L5S2-5 divided on the image side surface L5S2 of the fifth lens L5 are different from each other, and as a result, it can be seen that each area is formed of each different aspherical surface.

### Sixth Embodiment

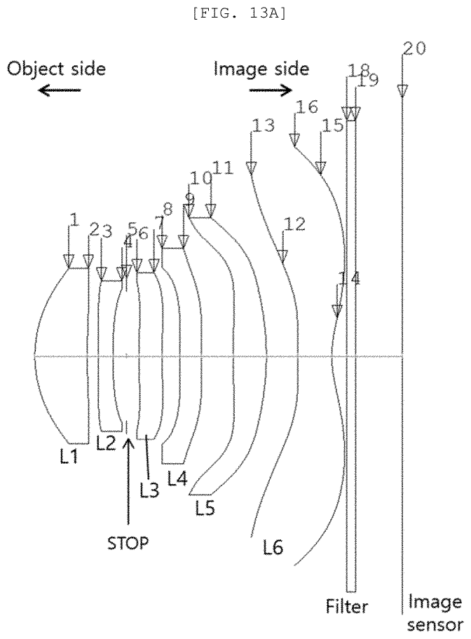

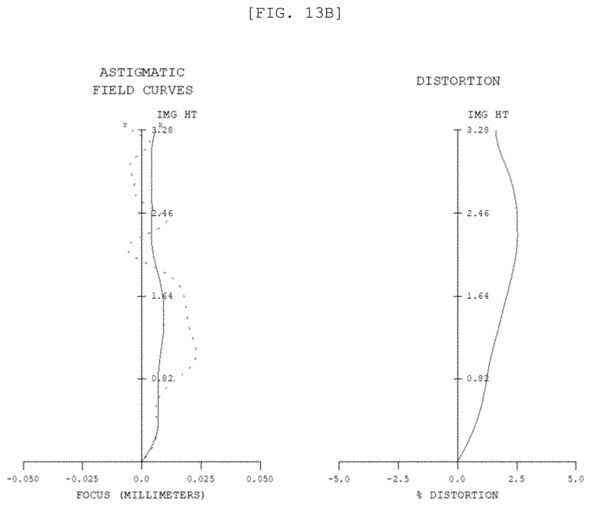

FIGS. 13A and 13B are a configuration diagram and a graph illustrating aberration curves of the optical imaging system according to a sixth embodiment of the present disclosure, respectively.

As illustrated in FIG. 13A, the optical imaging system according to the sixth embodiment of the present disclosure includes a first lens L1, a second lens L2, a third lens L3, a fourth lens L4, a fifth lens L5, and a sixth lens L6 which are disposed sequentially from an object side to an image side.

The first lens L1 has refractive power and may be a lens of which an object side surface is convex and an image side surface is concave.

The second lens L2 has refractive power and may be a lens of which both surfaces are concave in a paraxial region.

The third lens L3 has refractive power and may be a lens of which an object side surface is convex in a paraxial region and an image side surface is concave in a paraxial region.

The fourth lens L4 has refractive power and may be a lens of which an object side surface is convex in a paraxial region and an image side surface is concave in a paraxial region. In addition, the object side surface or the image side surface of the fourth lens L4 may be a plane or have large curvature close to a plane in the paraxial region.

The fifth lens L5 has refractive power and may be a lens of which both surfaces are convex in a paraxial region.

The sixth lens L6 has refractive power and may be a lens of which an object side surface is concave in a paraxial region and an image side surface is concave in a paraxial region. In addition, the object side surface or the image side surface of the sixth lens L6 may include at least one inflection point.

All lens surfaces of the first to sixth lenses L1, L2, L3, L4, L5, and L6 may also be aspherical surfaces, and at least one lens surface may also be a spherical surface.

However, in the optical imaging system according to the sixth embodiment of the present disclosure, an object side surface L6S1 of the sixth lens L6 is formed of a composite lens surface divided into two areas L6S1-1 and L6S1-2, and an image side surface L6S2 thereof is formed of a composite lens surface divided into three areas L6S2-1, L6S2-2, and L6S2-3.

The detailed design specification of the optical imaging system according to the sixth embodiment of the present disclosure is shown in the Table 13 below, and the aspherical coefficients applied to each lens surface are shown in the Table 14.

TABLE 13
Design specification according to sixth embodiment of the present disclosure

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 | 1st lens | L1 S1 | Asphere | 1.599 | 0.6926 | 1.544 | 55.91 |
| 2 | | L1 S2 | Asphere | 9.45 | 0.1494 | | |
| 3 | 2nd lens | L2 S1 | Asphere | −143 | 0.1889 | 1.671 | 19.24 |
| 4 | | L2 S2 | Asphere | 5.539 | 0.1804 | | |
| 5 | Stop | | Sphere | Infinity | 0.1658 | | |
| 6 | 3rd lens | L3 S1 | Asphere | 8.28 | 0.3041 | 1.615 | 25.95 |
| 7 | | L3 S2 | Asphere | 8.272 | 0.239 | | |
| 8 | 4th lens | L4 S1 | Asphere | 21.98 | 0.2837 | 1.615 | 25.95 |
| 9 | | L4 S2 | Asphere | 27.44 | 0.4169 | | |
| 10 | 5th lens | L5 S1 | Asphere | 11.72 | 0.4389 | 1.544 | 55.91 |
| 11 | | L5 S2 | Asphere | −3.126 | 0.4142 | | |
| 12 | 6th lens | L6 S1-1 | Asphere | 9.289 | — | 1.544 | 55.91 |
| 13 | | L6 S1-2 | Asphere | 7.34 | 0.4493 | | |
| 14 | | L6 S2-1 | Asphere | 1.412 | — | | |
| 15 | | L6 S2-2 | Asphere | 1.383 | — | | |
| 16 | | L6 S2-3 | Asphere | 1.354 | 0.1999 | | |
| 18 | Filter | | Sphere | Infinity | 0.11 | 1.517 | 64.17 |
| 19 | | | Sphere | Infinity | 0.6224 | | |
| 20 | Image | | Sphere | Infinity | | | |
| | sensor | | | | | | |

TABLE 14
Aspherical coefficients of sixth embodiment of the present disclosure

| | Surface name | | | | | | | |
|---|---|---|---|---|---|---|---|---|
| Surface | L1 S1 | L1 S2 | L2 S1 | L2 S2 | L3 S1 | L3 S2 | L4 S1 | L4 S2 |
| No. | 1 | 2 | 3 | 4 | 6 | 7 | 8 | 9 |
| R | 1.599E+00 | 9.450E+00 | −1.430E+02 | 5.539E+00 | 8.280E+00 | 8.272E+00 | 2.198E+01 | 2.744E+01 |
| k | 3.837E−01 | −9.015E−01 | 9.900E+01 | 1.257E+01 | 0.000E+00 | −3.773E+00 | −9.900E+01 | 0.000E+00 |
| A | −1.375E−02 | −3.283E−02 | −4.788E−02 | −2.727E−03 | −1.244E−01 | −1.358E−01 | −1.564E−01 | −1.599E−01 |
| B | −2.849E−02 | −8.330E−02 | 2.687E−01 | −4.681E−02 | 3.685E−01 | 1.857E−01 | −1.540E−01 | −4.321E−02 |
| C | 1.302E−01 | 5.499E−01 | −9.326E−01 | 1.931E+00 | −2.368E+00 | −4.182E−01 | 1.179E+00 | 3.464E−01 |
| D | −4.410E−01 | −1.735E+00 | 3.304E+00 | −1.060E+01 | 9.245E+00 | 1.664E−01 | −3.387E+00 | −6.455E−01 |
| E | 8.256E−01 | 3.318E+00 | −7.673E+00 | 3.317E+01 | −2.234E+01 | 1.267E+00 | 5.641E+00 | 6.678E−01 |
| F | −9.509E−01 | −3.971E+00 | 1.088E+01 | −5.831E+01 | 3.339E+01 | −3.249E+00 | −5.851E+00 | −3.967E−01 |
| G | 6.537E−01 | 2.883E+00 | −9.109E+00 | 6.264E+01 | −3.005E+01 | 3.609E+00 | 3.740E+00 | 1.341E−01 |
| H | −2.482E−01 | −1.158E+00 | 4.134E+00 | −3.674E+01 | 1.488E+01 | −2.000E+00 | −1.364E+00 | −2.390E−02 |
| J | 3.958E−02 | 1.976E−01 | −7.826E+01 | 9.084E+00 | −3.093E+00 | 4.538E−01 | 2.187E−01 | 1.729E−03 |
| | | Surface name | | | | | | |
| | Surface | L5 S1 | L5 S2 | L6 S1-1 | L6 S1-2 | L6 S2-1 | L6 S2-2 | L6 S2-3 |
| | No. | 10 | 11 | 12 | 13 | 14 | 15 | 16 |
| | R | 1.172E+01 | −3.126E+00 | 9.289E+00 | 7.340E+00 | 1.412E+00 | 1.383E+00 | −4.624E+00 |
| | k | 0.000E+00 | −2.264E−01 | −8.081E+00 | −8.081E+00 | −6.853E+00 | −7.601E+00 | 1.088E+00 |
| | A | −5.147E−03 | 5.048E−02 | −3.106E−01 | −2.372E−01 | 3.351E−02 | −1.351E−01 | 0.000E+00 |
| | B | −9.084E−02 | −6.077E−02 | 1.163E−01 | 8.749E−02 | 1.800E+00 | 8.670E−02 | 0.000E+00 |
| | C | 7.262E−02 | 6.191E−02 | 3.279E−01 | 7.966E−03 | −1.104E+02 | −4.277E−02 | 0.000E+00 |
| | D | −2.240E−02 | −3.774E−02 | −8.451E−01 | −1.692E−02 | 1.506E+03 | 1.632E−02 | 6.984E−04 |
| | E | −2.665E−02 | 5.174E−03 | 1.068E−00 | 6.278E−03 | −9.444E+03 | −4.700E−03 | −3.287E−04 |
| | F | 2.494E−02 | 4.403E−03 | −8.080E−01 | −1.205E−03 | 2.275E+04 | 9.517E−04 | 6.306E−05 |
| | G | −7.890E−03 | −2.121E−03 | 3.641E−01 | 1.309E−04 | −1.383E+04 | −1.245E−04 | −6.165E−06 |
| | H | 1.070E−03 | 3.624E−04 | −8.957E−02 | −7.561E−06 | −9.805E+04 | 9.332E−06 | 3.084E−07 |
| | J | −5.117E−05 | −2.240E−05 | 9.185E−03 | 1.787E−07 | 1.592E+05 | −3.019E−07 | −6.340E−09 |

In the optical imaging system according to the sixth embodiment of the present disclosure, a total length (TTL) is 4.86 mm, an effective focal length (EFL) is 4.24 mm, F-No is 1.9, and a diagonal length of an image sensor is 6.56 min.

Further, an effective radius (rₑ) of the object side surface L6S1 of the sixth lens L6 is 2.374 mm and a position divided into the two areas is r₁=1.215 mm.

Further, an effective radius (rₑ) of the image side surface L6S2 of the sixth lens L6 is 2.746 mm and positions divided into the three areas are r₂=0.499 mm and r₂=2.381 mm.

Through the Tables 13 and 14 above, it can be confirmed that all coefficient sets (R, k, A, B, C, D, E, F, G, H, J) applied to all the areas L6S1-1, L6S1-2, L6S2-1, L6S2-2, and L6S2-3 divided on the object side surface L6S1 and the image side surface L6S2 of the sixth lens L6 are different from each other, and as a result, it can be seen that each area is formed of each different aspherical surface.

### Seventh Embodiment

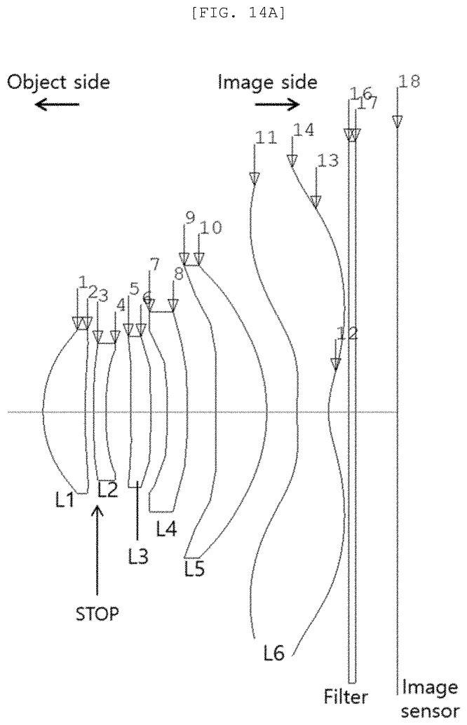

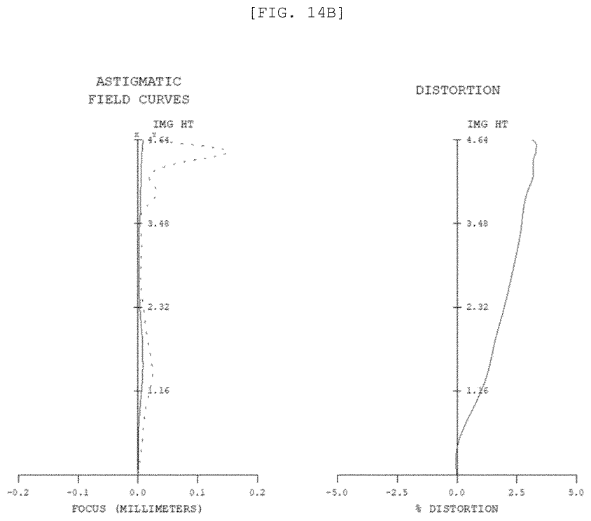

FIGS. 14A and 14B are a configuration diagram and a graph illustrating aberration curves of the optical imaging system according to a seventh embodiment of the present disclosure.

As illustrated in FIG. 14A, the optical imaging system according to the seventh embodiment of the present disclosure includes a first lens L1, a second lens L2, a third lens L3, a fourth lens L4, a fifth lens L5, and a sixth lens L6 which are disposed sequentially from an object side to an image side.

The first lens L1 has refractive power and may be a lens of which an object side surface is convex and an image side surface is concave.

The second lens L2 has refractive power and may be a lens of which an object side surface is convex and an image side surface is concave.

The third lens L3 has refractive power and may be a lens of which an object side surface is convex in a paraxial region and an image side surface is concave in a paraxial region.

The fourth lens L4 has refractive power and may be a lens of which an object side surface is concave and an image side surface is convex. In addition, the object side surface or the image side surface of the fourth lens L4 may be a plane or have large curvature close to a plane in the paraxial region.

The fifth lens L5 has refractive power and may be a lens of which both surfaces are convex in a paraxial region.

The sixth lens L6 has refractive power and may be a lens of which an object side surface is convex in a paraxial region and an image side surface is concave in a paraxial region. In addition, the object side surface or the image side surface of the sixth lens L6 may include at least one inflection point.

All lens surfaces of the first to sixth lenses L1, L2, L3, L4, L5, and L6 may also be aspherical surfaces, and at least one lens surface may also be a spherical surface.

However, in the optical imaging system according to the seventh embodiment of the present disclosure, an image side surface L6S2 of the sixth lens L6 is formed of a composite lens surface divided into three areas L6S2-1, L6S2-2, and L6S2-3.

The detailed design specification of the optical imaging system according to the seventh embodiment of the present disclosure is shown in the Table 15 below, and the aspherical coefficients applied to each lens surface are shown in the Table 16.

TABLE 15
Design specification according to seventh embodiment of the present disclosure

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 | 1st lens | L1 S1 | Asphere | 1.814 | 0.6922 | 1.535 | 55.71 |
| 2 | | L1 S2 | Asphere | 9.651 | 0.1402 | | |
| 3 (Stop) | 2nd lens | L2 S1 | Asphere | 20.96 | 0.2001 | 1.671 | 19.24 |
| 4 | | L2 S2 | Asphere | 5.012 | 0.4137 | | |
| 5 | 3rd lens | L3 S1 | Asphere | 19.45 | 0.3218 | 1.615 | 25.95 |
| 6 | | L3 S2 | Asphere | 31.18 | 0.2784 | | |
| 7 | 4th lens | L4 S1 | Asphere | −77.25 | 0.3227 | 1.615 | 25.95 |
| 8 | | L4 S2 | Asphere | 26.45 | 0.4757 | | |
| 9 | 5th lens | L5 S1 | Asphere | 21.65 | 0.8338 | 1.535 | 55.71 |
| 10 | | L5 S2 | Asphere | −2.846 | 0.4994 | | |
| 11 | 6th lens | L6 S1 | Asphere | 4.507 | 0.5172 | 1.535 | 55.71 |
| 12 | | L6 S2-1 | Asphere | 1.299 | — | | |
| 13 | | L6 S2-2 | Asphere | 1.366 | — | | |
| 14 | | L6 S2-3 | Asphere | 3.611 | 0.3348 | | |
| 16 | Filter | | Sphere | Infinity | 0.11 | 1.917 | 64.17 |
| 17 | | | Sphere | Infinity | 0.6900 | | |
| 18 | Image | | Sphere | Infinity | | | |
| | sensor | | | | | | |

TABLE 16
Aspherical coefficients of seventh embodiment of the present disclosure

| | Surface name | | | | | | |
|---|---|---|---|---|---|---|---|
| Surface | L1 S1 | L1 S2 | L2 S1 | L2 S2 | L3 S1 | L3 S2 | L4 S1 |
| No. | 1 | 2 | 3 | 4 | 5 | 6 | 7 |
| R | 1.814E+00 | 9.651E+00 | 2.096E+01 | 5.012E+00 | 1.945E+01 | 3.118E+01 | −7.725E+01 |
| k | 3.970E−01 | −4.431E+00 | 9.423E+01 | 1.672E+01 | 1.328E+01 | 2.494E+01 | −5.246E+01 |
| A | −1.207E−02 | −1.659E−02 | 1.603E−02 | −5.494E−03 | −5.953E−02 | −6.956E−02 | −1.213E−01 |
| B | 3.600E−02 | 2.032E−02 | 7.111E−02 | 2.897E−02 | 5.935E−02 | −1.020E−02 | 9.984E−03 |
| C | −1.445E−01 | −6.477E−02 | −1.321E−01 | 1.210E−01 | −2.491E−01 | 1.506E−01 | 7.514E−02 |
| D | 3.209E−01 | 1.896E−01 | 2.819E−01 | −6.863E−01 | 6.272E−01 | −5.323E−01 | −1.526E−01 |
| E | −4.484E−01 | −3.434E−01 | −4.229E−01 | 1.833E+00 | −1.070E+00 | 9.501E−01 | 1.749E−01 |
| F | 3.900E−01 | 3.688E−01 | 3.939E−01 | −2.834E+00 | 1.158E+00 | −1.029E+00 | −1.490E−01 |
| G | −2.063E−01 | −2.327E−01 | −2.132E−01 | 2.561E+00 | −7.520E−01 | 6.758E−01 | 9.054E−02 |
| H | 6.046E−02 | 7.973E−02 | 6.130E−02 | −1.250E+00 | 2.612E−01 | −2.478E−01 | −3.201E−02 |
| J | −7.592E−03 | −1.147E−02 | −2.122E−03 | 2.591E−01 | −3.507E−02 | 3.900E−02 | 4.686E−03 |
| | Surface name | | | | | | |
| Surface | L4 S2 | L5 S1 | L5 S2 | L6 S1 | L6 S2-1 | L6 S2-2 | L6 S2-3 |
| No. | 8 | 9 | 10 | 11 | 12 | 13 | 14 |
| R | 2.645E+01 | 2.165E+01 | −2.846E+00 | 4.507E+00 | 1.299E+00 | 1.366E+00 | 3.611E+00 |
| k | −1.174E+01 | −1.670E+00 | −9.464E−01 | −9.431E+01 | −7.988E+00 | −6.046E+00 | −1.313E+01 |
| A | −1.077E−01 | −2.160E−02 | −1.985E−02 | −1.922E−01 | −1.487E−02 | −8.054E−02 | −4.162E−02 |
| B | 3.181E−02 | −1.259E−02 | 2.902E−02 | 8.001E−02 | −7.620E−02 | 3.068E−02 | 7.727E−03 |
| C | −1.676E−02 | −1.265E−03 | −3.624E−02 | −1.801E−02 | 7.972E−02 | −7.450E−03 | 7.648E−04 |
| D | 4.589E−02 | 9.724E−03 | 2.577E−02 | 2.617E−03 | −3.345E−02 | 1.178E−03 | −3.929E−04 |
| E | 6.619E−02 | −6.724E−03 | −1.034E−02 | −2.568E−04 | 7.226E−03 | −1.220E−04 | 5.030E−05 |
| F | 4.999E−02 | 2.139E−03 | 2.447E−03 | 1.699E−05 | −8.895E−04 | 8.868E−06 | −3.217E−06 |
| G | −2.026E−02 | −3.516E−04 | −3.414E−04 | −7.278E−07 | 6.368E−05 | −3.205E−07 | 1.128E−07 |
| H | 4.180E−03 | 2.872E−05 | 2.611E−05 | 1.824E−08 | −2.489E−06 | 6.765E−09 | −2.074E−09 |
| J | −3.463E−04 | −9.092E−07 | −8.450E−07 | −2.030E−10 | 4.131E−08 | −5.573E−11 | 1.565E−11 |

In the optical imaging system according to the seventh embodiment of the present disclosure, a total length (TTL) is 5.83 mm, an effective focal length (EFL) is 4.98 mm, F-No is 2.0, and a diagonal length of an image sensor is 9.27 min.

Further, an effective radius (rₑ) of the image side surface L6S2 of the sixth lens L6 is 3.999 mm and positions divided into the three areas are r₂=0.663 mm and r₂=3.333 mm.

Through the Tables 15 and 16 above, it can be confirmed that all coefficient sets (R, k, A, B, C, D, E, F, G, H, J) applied to the three areas L6S2-1, L6S2-2, and L6S2-3 divided on the image side surface L6S2 of the sixth lens L6 are different from each other, and as a result, it can be seen that each area is formed of each different aspherical surface.

### Eighth Embodiment

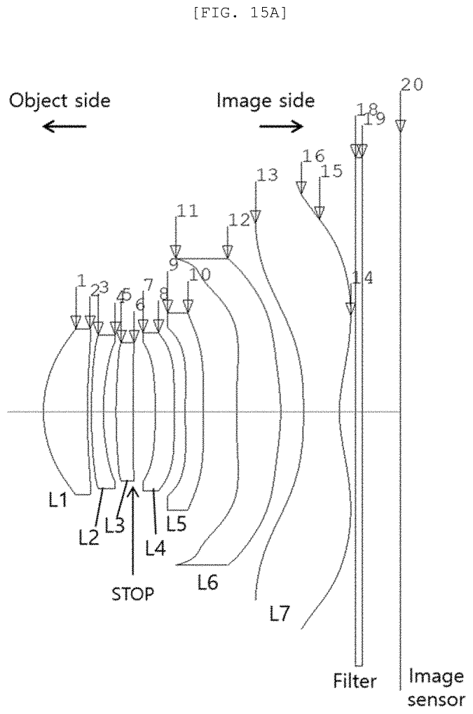

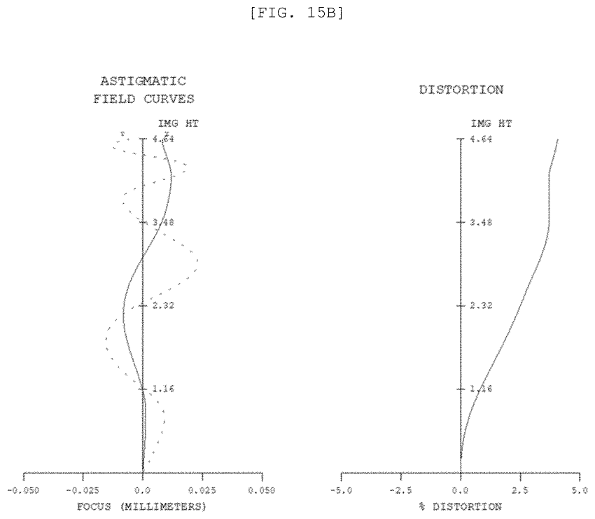

FIGS. 15A and 15B are a configuration diagram and a graph illustrating aberration curves of the optical imaging system according to an eighth embodiment of the present disclosure.

As illustrated in FIG. 15A, the optical imaging system according to the eighth embodiment of the present disclosure includes a first lens L1, a second lens L2, a third lens L3, a fourth lens L4, a fifth lens L5, a sixth lens L6, and a seventh lens L7 which are disposed sequentially from an object side to an image side.

The first lens L1 has refractive power and may be a lens of which an object side surface is convex and an image side surface is concave.

The second lens L2 has refractive power and may be a lens of which an object side surface is convex and an image side surface is concave.

The third lens L3 has refractive power and may be a lens of which an object side surface is convex and an image side surface is concave.

The fourth lens L4 has refractive power, wherein an object side surface may be concave in a paraxial region and an image side surface may be a plane or a concave surface having large curvature close to a plane.

The fifth lens L5 has refractive power and may be a lens of which an object side surface is convex in a paraxial region and an image side surface is concave in a paraxial region.

The sixth lens L6 has refractive power and may be a lens of which both surfaces are convex in a paraxial region.

The seventh lens L7 has refractive power and may be a lens of which both surfaces are concave in a paraxial region.

In addition, the object side surface or the image side surface of the seventh lens L7 may include at least one inflection point.

All lens surfaces of the first to seventh lenses L1, L2, L3, L4, L5, L6, and L7 may also be aspherical surfaces, and at least one lens surface may also be a spherical surface.

However, in the optical imaging system according to the eighth embodiment of the present disclosure, an image side surface L7S2 of the seventh lens L7 is formed of a composite lens surface divided into three areas L7S2-1, L7S2-2, and L7S2-3.

The detailed design specification of the optical imaging system according to the eighth embodiment of the present disclosure is shown in the Table 17 below, and the aspherical coefficients applied to each lens surface are shown in Table 18.

TABLE 17
Design specification according to eighth embodiment of the present disclosure

| | | | | Radius of | Thickness/ | Refractive | Abbe |
|---|---|---|---|---|---|---|---|
| Surface | | Surface | Sphere/ | Curvature | distance | Index | Number |
| No. | Component | Name | Asphere | (mm) | (mm) | (Nd) | (Vd) |
| 1 | 1st lens | L1 S1 | Asphere | 1.931 | 0.7341 | 1.544 | 55.91 |
| 2 | | L1 S2 | Asphere | 9.512 | 0.067 | | |
| 3 | 2nd lens | L2 S1 | Asphere | 7.336 | 0.2 | 1.671 | 19.24 |
| 4 | | L2 S2 | Asphere | 3.773 | 0.2131 | | |
| 5 | 3rd lens | L3 S1 | Asphere | 8.932 | 0.2813 | 1.535 | 55.71 |
| 6 (Stop) | | L3 S2 | Asphere | 24.23 | 0.3716 | | |
| 7 | 4th lens | L4 S1 | Asphere | −11.33 | 0.3191 | 1.615 | 25.95 |
| 8 | | L4 S2 | Asphere | 100.9 | 0.1614 | | |
| 9 | 5th lens | L5 S1 | Asphere | 7.477 | 0.2969 | 1.65 | 21.47 |
| 10 | | L5 S2 | Asphere | 10.85 | 0.5604 | | |
| 11 | 6th lens | L6 S1 | Asphere | 12.4 | 0.7373 | 1.535 | 55.71 |
| 12 | | L6 S2 | Asphere | −3.257 | 0.3837 | | |
| 13 | 7th lens | L7 S1 | Asphere | −7.305 | 0.5973 | 1.544 | 55.91 |
| 14 | | L7 S2-1 | Asphere | 2.246 | — | | |
| 15 | | L7 S2-2 | Asphere | 2.446 | — | | |
| 16 | | L7 S2-3 | Asphere | 2.218 | 0.2699 | | |
| 18 | Filter | | Sphere | Infinity | 0.11 | 1.517 | 64.17 |
| 19 | | | Sphere | Infinity | 0.6400 | | |
| 20 | Image | | Sphere | Infinity | | | |
| | sensor | | | | | | |

TABLE 18
Aspherical coefficients of eighth embodiment of the present disclosure

| | Surface name | | | | | | | |
|---|---|---|---|---|---|---|---|---|
| Surface | L1 S1 | L1 S2 | L2 S1 | L2 S2 | L3 S1 | L3 S2 | L4 S1 | L4 S2 |
| No. | 1 | 2 | 3 | 4 | 5 | 6 | 7 | 8 |
| R | 1.931E+00 | 9.512E+00 | 7.336E+00 | 3.773E+00 | 8.932E+00 | 2.423E+01 | −1.133E+01 | 1.009E+02 |
| k | −1.594E+00 | 0.000E+00 | 0.000E+00 | 3.006E+00 | −3.169E+01 | −1.000E+00 | −3.362E+02 | 2.455E+03 |
| A | 2.174E−02 | −2.609E−02 | −3.776E−02 | −2.960E−02 | −1.173E−03 | −1.193E−02 | −1.001E−01 | −1.362E−01 |
| B | 2.673E−02 | 3.116E−02 | 2.782E−02 | 4.146E−02 | −9.107E−03 | 1.850E−02 | 9.782E−02 | 2.432E−01 |
| C | −7.442E−02 | −4.511E−02 | 2.532E−02 | −9.617E−02 | −2.296E−02 | −9.903E−02 | −2.136E−01 | −6.135E−01 |
| D | 1.290E−01 | 5.262E−02 | −1.081E−01 | 1.800E−01 | 7.363E−02 | 2.127E−01 | 2.310E−01 | 1.092E+00 |
| E | −1.397E−01 | −3.747E−02 | 1.942E−01 | −1.928E−01 | −9.011E−02 | −2.388E−01 | −1.444E−01 | −1.369E+00 |
| F | 9.454E−02 | 9.985E−03 | −2.036E−01 | 1.100E−01 | 6.192E−02 | 1.349E−01 | 4.413E−02 | 1.121E+00 |
| G | −3.900E−02 | 3.560E−03 | 1.260E−01 | −2.452E−02 | −1.505E−02 | −5.075E−03 | −3.411E−03 | −5.659E−01 |
| H | 8.879E−03 | −2.929E−03 | −4.216E−02 | 0.000E+00 | 0.000E+00 | −2.921E−02 | 0.000E+00 | 1.592E−01 |
| J | −8.597E−04 | 5.273E−04 | 5.852E−03 | 0.000E+00 | 0.000E+00 | 9.980E−03 | 0.000E+00 | −1.895E−02 |
| | Surface name | | | | | | | |
| Surface | L5 S1 | L5 S2 | L6 S1 | L6 S2 | L7 S1 | L7 S2-1 | L7 S2-2 | L7 S2-3 |
| No. | 9 | 10 | 11 | 12 | 13 | 14 | 15 | 16 |
| R | 7.477E+00 | 1.085E+01 | 1.240E+01 | −3.257E+00 | −7.305E+00 | 2.246E+00 | 2.446E+00 | −4.436E+00 |
| k | −2.477E+02 | 0.000E+00 | 1.956E+01 | −7.017E−02 | −1.453E+00 | −9.260E+00 | −9.685E+00 | −1.078E+00 |
| A | −1.099E−01 | −1.255E−01 | 1.336E−02 | 1.033E−01 | −4.027E−02 | −4.587E−02 | −4.104E−02 | 0.000E+00 |
| B | 4.092E−02 | 5.468E−02 | −4.508E−02 | −5.361E−02 | 6.819E−03 | 1.635E−02 | 1.372E−02 | 0.000E+00 |
| C | 1.000E−02 | −1.512E−02 | 3.009E−02 | 1.602E−02 | 3.146E−04 | −5.165E−03 | −4.356E−03 | 0.000E+00 |
| D | −3.809E−02 | 8.121E−03 | −1.796E−02 | −3.352E−03 | −1.765E−04 | 1.169E−03 | 1.034E−03 | 0.000E+00 |
| E | 1.638E−02 | −1.261E−02 | 7.544E−03 | 6.188E−04 | 1.867E−05 | −1.710E−04 | −1.665E−04 | 5.825E−06 |
| F | −1.965E−03 | 8.933E−03 | −2.032E−03 | −6.422E−05 | −8.564E−07 | 1.574E−05 | 1.746E−05 | −1.916E−06 |
| G | 0.000E+00 | −2.930E−03 | 3.325E−04 | 3.111E−06 | 1.477E−08 | −8.835E−07 | −1.147E−06 | 2.021E−07 |
| H | 0.000E+00 | 4.569E−04 | −2.960E−05 | −1.139E−08 | 0.000E+00 | 2.794E−08 | 4.293E−08 | −9.475E−09 |
| J | 0.000E+00 | −2.749E−05 | 1.083E−06 | −3.027E−09 | 0.000E+00 | −3.858E−10 | −6.975E−10 | 1.663E−10 |

In the optical imaging system according to the eighth embodiment of the present disclosure, a total length (TTL) is 5.96 mm, an effective focal length (EFL) is 5.24 mm, F-No is 1.9, and a diagonal length of an image sensor is 9.27 min.

Further, an effective radius (rₑ) of the image side surface L7S2 of the seventh lens L7 is 3.615 mm and positions divided into the three areas are r_{1=1.6} mm and r₂=3.2 mm.

Through the Tables 17 and 18 above, it can be confirmed that all coefficient sets (R, k, A, B, C, D, E, F, G, H, J) applied to the three areas L7S2-1, L7S2-2, and L7S2-3 divided on the image side surface L7S2 of the seventh lens L7 are different from each other, and as a result, it can be seen that each area is formed in each different aspherical surface.

Hereinabove, the case of applying the composite lens surface to the last lens surface among the plurality of lens surfaces constituting the optical system has been mainly described, but like the third embodiment, the composite lens surfaces may be applied to all the lens surfaces constituting the optical system and the composite lens surfaces may also be applied to at least two or more lens surfaces.

In addition, hereinabove, it has been described that the aspherical or spherical surface is formed on each divided area, but it is not necessarily limited thereto. Therefore, a plane may also be formed in at least one area of the divided areas. Also, since the aspherical surface is not necessarily formed in the divided area, only spherical surfaces with different curvatures may also be formed in all the areas.

Further, hereinabove, although it has been described that all of the plurality of divided areas have curved surfaces with each different shapes, it is not limited thereto, and thus, non-adjacent areas (e.g., first area and third area) may be formed of aspherical, spherical, or planar surfaces expressed by the same equation while only the adjacent areas are formed of different shapes from each other.

Further, hereinabove, although it has been mainly described that each area is rotationally symmetric, it is not limited thereto, and thus, each divided area may be formed of any one of non-rotational symmetric and freeform surfaces.

2. Design Method of Composite Lens Surface

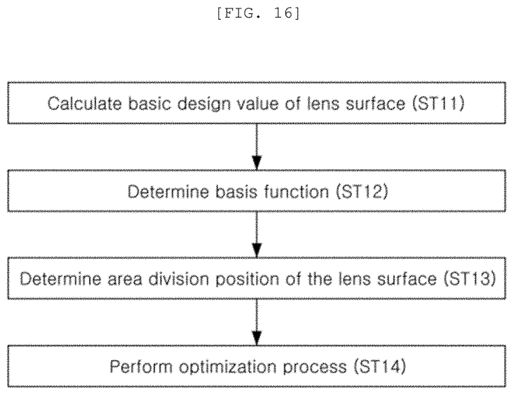

Hereinafter, a detailed method of designing the composite lens surface described above will be described with reference to a flowchart of FIG. 16.

First, it is preferred to calculate basic design values of a lens surface based on a target specification by using a design algorithm of existing optical design software (e.g., CodeV, Zemax, OSLO, etc.).

At this time, the basic design values of the lens surface may be calculated by inputting basic data such as the number of lenses, a focal length, a field of view (FOV), a magnification, and the positions and sizes of an entrance pupil and an exit pupil, restriction conditions, and the like. (ST11)

After the basic design values of the lens surface are calculated, a basis including a basis element having large similarity in a predetermined range of the calculated basic design values is determined by searching basis element candidate groups.

As the basis element may be expressed as a function, the basis element candidate groups may be a basis function candidate groups.

In the basis function candidate groups, as described above, an x aspherical function, a Q_{con} aspherical function, a Q_{bsf} aspherical function, a Zernike function, and the like may be included.

Meanwhile, the similarity between the basic design values of the lens surface and the basis element may also be determined based on designer's experiences, but it is more preferable to utilize a mathematical algorithm to determine the similarity.

As an example, the similarity (s) may be calculated in the same manner as the following Equation 6 in a range [a, b].

s=sim[{z(r)−z_{c}(r)},fᵢ(r)]ₐ^{b} <Equation 6>

Here, r represents a radial distance, z(r) represents a sag of the lens surface, z_{c}(r) represents a conic term of the lens surface, and fᵢ(r) represents an i-th basis element.

Meanwhile, the range [a, b] may be determined and arbitrarily input by the designer and may also be automatically selected and input according to features such as an inflection point and the like or setting conditions by a program.

As an example, in the case of using the orthonormal basis function, the similarity (s) may be calculated through an inner product value in the same manner as in the following Equation 7.

$$s = \frac{{r}_{e}}{b - a} {\int }_{a}^{b} \{ z ( r ) - {z}_{c} ( r ) \} {f}_{i} ( r ) d r \qquad < Equation 7 >$$

Wherein, r represents a radial distance, z(r) represents a sag of the lens surface, z_{c}(r) represents a conic term of the lens surface, fᵢ(r) represents an i-th basis element, a and b are divided positions of each area, and rₑ represents an effective radius of the lens surface.

Meanwhile, the similarity (s) may be defined using an average of standard deviation and residual value deviation, etc., by applying the method of least squares, and the like, and in this case, preferably, the similarity is defined by considering an appropriate data number.

When there is a basis element in which the similarity (s) satisfies the setting condition through the above process, it is determined as the basis element similar to the form of the corresponding area, and the basis including the basis element may be determined as a basis to be applied to the corresponding area.

At this time, it is preferred that a first curved surface function represented by a first basis function applied to a first area and a second curved surface function represented by a second basis function applied to a second area adjacent to the first area are determined so that the sag heights of the lens surface is the same or the slope is the same on the boundary between the first area and the second area. (ST12)

Meanwhile, since the similarity (s) is calculated under a condition of a predetermined range [a, b], the range [a, b] may be determined as the boundary of the corresponding area when the basis including a basis element of which the similarity (s) within the predetermined range [a, b] satisfies the predetermined condition is determined.

However, in some cases, an inflection point of the lens surface may also be determined as an initial position of area division by considering the configuration of the basis function and the form of the lens surface. Otherwise, the area division positions may also be determined by other different methods. (ST13)

After the division positions of the corresponding lens surface and the basis element corresponding to each area are determined through the above process, an optimization process may be performed considering mass-productivity and the like. (ST14)

3. Computing Device for Designing Composite Lens Surface

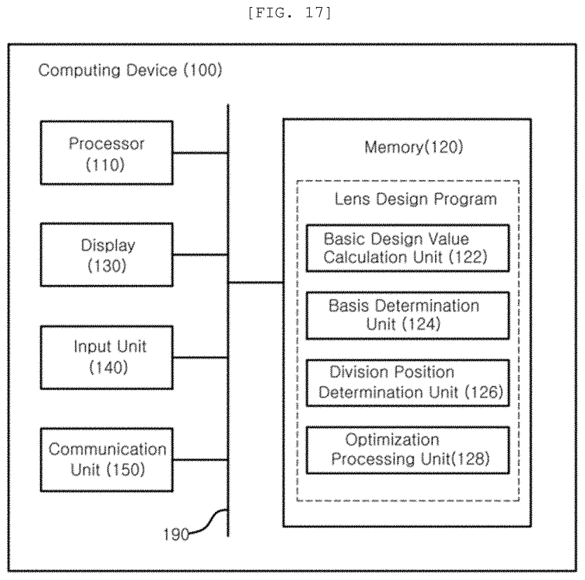

As shown in the block diagram of FIG. 17, a computing device 100 according to an embodiment of the present disclosure may include a processor 110, a memory 120, a display 130, an input unit 140, a communication unit 150, etc.

The processor 110 executes a computer program stored in the memory 120 to execute predetermined computing or data processing.

The memory 120 may include a nonvolatile memory (e.g., a flash memory, etc.) and a volatile memory (e.g., a random access memory). The memory 120 may include a large-capacity storage, such as HDD, SSD, ODD, and the like. The memory 120 may store computer programs, various parameters, data, etc. for the operation of the computing device 100. The computer program is a set of instructions executed by the processor 110 and may include an operating system, middleware, an application or an application programming interface (API), etc. The computer program may be stored in a non-volatile memory and loaded and executed in a volatile memory.

In the computing device 100 according to an embodiment of the present disclosure, a lens design program for designing the composite lens surface of the lens surface may be stored in the memory 120.

The lens design program may include a basic design value calculation unit 122, a basis determination unit 124, a division position determination unit 126, an optimization processing unit 128, and the like, which are functionally distinguished.

The basic design value calculation unit 122 serves to calculate basic design values of each lens surface based on inputted data while providing an interface capable of allowing the user to input a target specification, basic data, restriction conditions, and the like required for lens design. In the basic design value calculation unit 122, existing optical design programs may also be used.

The basis determination unit 124 calculates the similarity (s) to the basic design values of the lens surface in a predetermined range by searching basis function candidate groups and basis elements stored in the memory 120, and determines a basis including the basis element of which the calculated similarity satisfies the predetermined condition as the basis of the corresponding area. The method of calculating the similarity is as described above.

The division position determination unit 126 determines the range predetermined when the basis determination unit 124 determines the basis as a division position or determines a position preset by the user or satisfying a predetermined condition as the division position.

The optimization processing unit 128 performs existing optimization algorithms according to the predetermined condition or provides an interface for optimization to the user and adjusts existing design values according to input data.

Referring back to FIG. 17, the display 130 serves to display a lens design result or provide a data input window, the input unit 140 provides an interface for user operation and instructions/data input, and the communication unit 150 provides a communication interface with external or remote electronic devices. Further, a data transmission line 190 serves as a medium of transmitting an electric signal among the respective components 110, 120, 130, 140, and 150 of the computing device 100.

The lens design method according to the embodiment of the present disclosure may be implemented in a form of program instructions which may be performed through various computer means to be recorded in a computer readable recording medium.

At this time, the computer readable recording medium may include program instructions, data files, data structures, and the like alone or in combination. The program instructions recorded in the recording medium may be specially designed and configured for the present disclosure, or may be known to those skilled in the computer software-related art to be usable.

The computer readable recording medium may include at least one of magnetic media, such as a hard disk, a floppy disk, and a magnetic tape, optical media such as a CD-ROM and a DVD, magneto-optical media such as a floptical disk, a ROM, a RAM, a flash memory, and the like.

In addition, the program instructions may include high-level language codes executable by a computer using an interpreter and the like, as well as machine language codes created by a compiler.

Hereinabove, the preferred embodiment of the present disclosure has been described, but the present disclosure is not limited to the embodiments described above and may be variously modified or changed in a specific application process, and it is natural that if the modified or changed embodiments also include the technical idea of the present disclosure disclosed in the appended claims, the modified or changed embodiments belong to the scope of the present disclosure.

What is claimed is:

1. An optical imaging system comprising one or more lens surfaces divided into a plurality of areas,
wherein adjacent areas among the plurality of areas are surfaces expressed by different equations, and
light passing through each of the plurality of areas is imaged on the image surface of the same image sensor.

2. The optical imaging system of claim 1, wherein the adjacent areas among the plurality of areas are aspherical or spherical surfaces expressed by different equations.

3. The optical imaging system of claim 1, wherein the adjacent areas among the plurality of areas have the same sag height of the lens surface or the same slope on the boundary.

4. The optical imaging system of claim 1, wherein the plurality of areas are one of a rotationally symmetric surface, a non-rotationally symmetric surface, and a freeform surface, respectively.

5. The optical imaging system of claim 1, wherein the plurality of areas is formed on the last lens surface of the optical system.

6. The optical imaging system of claim 1, wherein the plurality of areas include two or more of plurality of areas from a first area to an n-th area and a sag (Z(r)) of the lens surface of each area is calculated by the following Equation.
$$Z ( r ) = \frac{\frac{{( r - {d}_{1} )}^{2}}{{R}_{1}}}{1 + \sqrt{1 - ( 1 + {k}_{1} ) \frac{{( r - {d}_{1} )}^{2}}{{R}_{1}^{2}}}} + {{A}_{1} ( r - {d}_{1} )}^{4} + {{B}_{1} ( r - {d}_{1} )}^{6} + {{C}_{1} ( r - {d}_{1} )}^{8} . . . ( \vert r \vert \leq {r}_{1} )$$
$$Z ( r ) = \frac{\frac{{( r - {d}_{2} )}^{2}}{{R}_{2}}}{1 + \sqrt{1 - ( 1 + {k}_{2} ) \frac{{( r - {d}_{2} )}^{2}}{{R}_{2}^{2}}}} + {{A}_{2} ( r - {d}_{2} )}^{4} + {{B}_{2} ( r - {d}_{2} )}^{6} + {{C}_{2} ( r - {d}_{2} )}^{8} . . . ( {r}_{1} \leq \vert r \vert \leq {r}_{2} ) \\ . . . \\ Z ( r ) = \frac{\frac{{( r - {d}_{i} )}^{2}}{{R}_{i}}}{1 + \sqrt{1 - ( 1 + {k}_{i} ) \frac{{( r - {d}_{i} )}^{2}}{{R}_{i}^{2}}}} + {{A}_{i} ( r - {d}_{i} )}^{4} + {{B}_{i} ( r - {d}_{i} )}^{6} + {{C}_{i} ( r - {d}_{i} )}^{8} . . . ( {r}_{i - 1} \leq \vert r \vert \leq {r}_{i} ) \\ . . . \\ Z ( r ) = \frac{\frac{{( r - {d}_{n} )}^{2}}{{R}_{n}}}{1 + \sqrt{1 - ( 1 + {k}_{n} ) \frac{{( r - {d}_{n} )}^{2}}{{R}_{n}^{2}}}} + {{A}_{n} ( r - {d}_{n} )}^{4} + {{B}_{n} ( r - {d}_{n} )}^{6} + {{C}_{n} ( r - {d}_{n} )}^{8} . . . ( {r}_{n - 1} \leq \vert r \vert \leq {r}_{c} )$$
(r represents a radial distance, rₑ represents an effective radius of the lens, |r|r₁ represents a range of a first area, r₁≤|r|≤r₂ represents a range of a second area, rᵢ₋₁≤|r|≤rᵢ represents a range of an i-th area, rₙ₋₁≤|r|≤rₑ represents a range of an n-th area, and d₁, d₂, . . . dₙ represent reference positions of the radial distance in each area and are the number including 0).

7. The optical imaging system of claim 1, wherein the adjacent areas among the plurality of areas are expressed by the same or different basis functions selected from an xⁿ aspherical function, a Q_{con} aspherical function, a Q_{bsf} aspherical function, and a Zernike function.

8. An imaging device comprising:
an image sensor; and
an optical imaging system including one or more lens surfaces divided into a plurality of areas, wherein adjacent areas among the plurality of areas are surfaces expressed by different equations, and light passing through each of the plurality of areas is imaged on the image surface of the image sensor.

9. The imaging device of claim 8, wherein the adjacent areas among the plurality of areas of the optical imaging system are aspherical or spherical surfaces expressed by different equations.

10. The imaging device of claim 8, wherein the plurality of areas of the optical imaging system include two or more of plurality of areas from a first area to an n-th area and a sag (Z(r)) of the lens surface of each area is calculated by the following Equation.
$$Z ( r ) = \frac{\frac{{( r - {d}_{1} )}^{2}}{{R}_{1}}}{1 + \sqrt{1 - ( 1 + {k}_{1} ) \frac{{( r - {d}_{1} )}^{2}}{{R}_{1}^{2}}}} + {{A}_{1} ( r - {d}_{1} )}^{4} + {{B}_{1} ( r - {d}_{1} )}^{6} + {{C}_{1} ( r - {d}_{1} )}^{8} . . . ( \vert r \vert \leq {r}_{1} )$$
$$Z ( r ) = \frac{\frac{{( r - {d}_{2} )}^{2}}{{R}_{2}}}{1 + \sqrt{1 - ( 1 + {k}_{2} ) \frac{{( r - {d}_{2} )}^{2}}{{R}_{2}^{2}}}} + {{A}_{2} ( r - {d}_{2} )}^{4} + {{B}_{2} ( r - {d}_{2} )}^{6} + {{C}_{2} ( r - {d}_{2} )}^{8} . . . ( {r}_{1} \leq \vert r \vert \leq {r}_{2} ) \\ . . . \\ Z ( r ) = \frac{\frac{{( r - {d}_{i} )}^{2}}{{R}_{i}}}{1 + \sqrt{1 - ( 1 + {k}_{i} ) \frac{{( r - {d}_{i} )}^{2}}{{R}_{i}^{2}}}} + {{A}_{i} ( r - {d}_{i} )}^{4} + {{B}_{i} ( r - {d}_{i} )}^{6} + {{C}_{i} ( r - {d}_{i} )}^{8} . . . ( {r}_{i - 1} \leq \vert r \vert \leq {r}_{i} ) \\ . . . \\ Z ( r ) = \frac{\frac{{( r - {d}_{n} )}^{2}}{{R}_{n}}}{1 + \sqrt{1 - ( 1 + {k}_{n} ) \frac{{( r - {d}_{n} )}^{2}}{{R}_{n}^{2}}}} + {{A}_{n} ( r - {d}_{n} )}^{4} + {{B}_{n} ( r - {d}_{n} )}^{6} + {{C}_{n} ( r - {d}_{n} )}^{8} . . . ( {r}_{n - 1} \leq \vert r \vert \leq {r}_{c} )$$
(r represents a radial distance, rₑ represents an effective radius of the lens, |r|≤r₁ represents a range of a first area, r₁≤|r|≤r₂ represents a range of a second area, rᵢ₋₁≤|r|≤rᵢ represents a range of an i-th area, rₙ₋₁≤|r|≤rₑ represents a range of an n-th area, and d₁, d₂, . . . dₙ represent reference positions of the radial distance in each area and are the number including 0).

11. A method of designing a composite lens surface to be applied to a lens surface of an optical imaging system, the method comprising the steps of:
calculating basic design values of a lens surface using inputted basic data; and
determining a basis including a basis element of which similarity (s) satisfies a predetermined condition as compared with the basic design values for a predetermined range on the lens surface, but determining coefficients of the basis so that sag heights of a lens surface by a curved surface function of a first area and a lens surface by a curved surface function of a second area are the same or slopes are the same as each other on a boundary of the first area and the second area adjacent to each other.

12. The method of designing the composite lens surface of claim 11, wherein when determining the basis including the basis element of which the similarity (s) satisfies the predetermined condition as compared with the basic design values, the similarity (s) is calculated using the following Equation in the predetermined range.
s=sim[{z(r)−z_{c}(r)},fᵢ(r)]ₐ^{b}
(r represents a radial distance, z(r) represents a sag of the lens surface, z_{c}(r) represents a conic term of the lens surface, fᵢ(r) represents an i-th basis element, and a and b represent surface area division positions, respectively.)

13. The method of designing the composite lens surface of claim 11, wherein when determining the basis including the basis element of which the similarity (s) satisfies the predetermined condition as compared with the basic design values, in the case that the basis consists of orthonormal basis elements, the similarity (s) is calculated using the following Equation.
$$s = \frac{{r}_{e}}{b - a} {\int }_{a}^{b} \{ z ( r ) - {z}_{c} ( r ) \} {f}_{i} ( r ) d r$$
(r represents a radial distance, z(r) represents a sag of the lens surface, z_{c}(r) represents a conic term of the lens surface, fᵢ(r) represents an i-th basis element, a and b represent surface area division positions, respectively, and rₑ represents an effective radius of the lens surface.)

14. A computer readable recording medium including a program executed by a processor to execute a design method of a composite lens surface to be applied to a lens surface of an optical imaging system, wherein
the design method comprises the steps of:
calculating basic design values of a lens surface using inputted basic data; and
determining a basis including a basis element of which similarity (s) satisfies a predetermined condition as compared with the basic design values for a predetermined range on the lens surface, but determining coefficients of the basis so that sag heights of a lens surface by a curved surface function of a first area and a lens surface by a curved surface function of a second area are the same or slopes are the same as each other on a boundary of the first area and the second area adjacent to each other.
